(19) United States
(12) Patent Application Publication
(10) Pub. No.: US 2015/0357400 A1
(43) Pub. Date: Dec. 10, 2015

(54) SEMICONDUCTOR DEVICE

(71) Applicant: Renesas Electronics Corporation, Kawasaki-shi (JP)

(72) Inventors: Takahisa FURUHASHI, Kawasaki-shi (JP); Masahiro MATSUMOTO, Kawasaki-shi (JP)

(21) Appl. No.: 14/711,471

(22) Filed: May 13, 2015

(30) Foreign Application Priority Data
Jun. 4, 2014 (JP) 2014-116279

(51) Int. Cl. H01L 49/02; H01L 23/528; H01L 23/532; H01L 27/06

(52) U.S. Cl. CPC H01L 28/60; H01L 28/20; H01L 27/0629; H01L 23/528; H01L 23/53214

(57) ABSTRACT

A semiconductor device having a capacitor, which provides enhanced reliability. A wiring and a capacitor are formed over an interlayer insulating film overlying a semiconductor substrate and another interlayer insulating film is formed over the interlayer insulating film so as to cover the wiring and capacitor. The capacitor includes a lower electrode overlying the interlayer insulating film, an upper electrode overlying the interlayer insulating film to cover the lower electrode at least partially, and a capacitive insulating film interposed between the lower and upper electrodes. The upper electrode and the wiring are formed from a conductive film pattern in the same layer. A plug is located under, and electrically coupled to, the lower electrode and another plug is located over the upper electrode's portion not overlapping the lower electrode in plan view and electrically coupled to the upper electrode. Another plug is located over, and electrically coupled to, the wiring.

### CROSS-REFERENCE TO RELATED APPLICATIONS

The disclosure of Japanese Patent Application No. 2014-116279 filed on Jun. 4, 2014 including the specification, drawings and abstract is incorporated herein by reference in its entirety.

### BACKGROUND

The present invention relates to semiconductor devices and more particularly to semiconductor devices having capacitors.

Various semiconductor devices are manufactured by forming a MISFET and a capacitor over a semiconductor substrate and interconnecting elements by wirings. Among capacitors, there are MIM capacitors.

Japanese Unexamined Patent Application Publication Nos. 2001-313370, 2004-119461, and 2004-266005 describe techniques for semiconductor devices having MIM capacitors.

### SUMMARY

The reliability of a semiconductor device having a capacitor is expected to be enhanced.

The above and further objects and novel features of the invention will more fully appear from the following detailed description in this specification and the accompanying drawings.

According to one aspect of the invention, there is provided a semiconductor device which includes a first wiring and a capacitor which are formed over a first interlayer insulating film over a semiconductor substrate, and a second interlayer insulating film formed over the first interlayer insulating so as to cover the first wiring and the capacitor. The capacitor includes a lower electrode formed over the first interlayer insulating film, an upper electrode formed over the first interlayer insulating film so as to cover the lower electrode at least partially, and a capacitive insulating film interposed between the lower electrode and the upper electrode. The first wiring and the upper electrode are formed from a conductive film pattern in a layer. The semiconductor device further includes a first contact plug located under the lower electrode and electrically coupled to the lower electrode, a second contact plug located over or under the upper electrode and electrically coupled to the upper electrode, and a third contact plug located over the first wiring and electrically coupled to the first wiring. The second contact plug is located over or under the upper electrode's portion not overlapping the lower electrode in plan view.

According to the invention, the reliability of the semiconductor device is enhanced.

### BRIEF DESCRIPTION OF THE DRAWINGS

FIG. 1 is a sectional view of an essential part of a semiconductor device according to a first embodiment of the invention;

FIG. 2 is a plan view of the essential part of the semiconductor device according to the first embodiment;

FIG. 3 is a sectional view of the essential part of the semiconductor device in a manufacturing step according to the first embodiment;

FIG. 4 is a sectional view of the essential part of the semiconductor device in a manufacturing step next to the step of FIG. 3;

FIG. 5 is a sectional view of the essential part of the semiconductor device in a manufacturing step next to the step of FIG. 4;

FIG. 6 is a sectional view of the essential part of the semiconductor device in a manufacturing step next to the step of FIG. 5;

FIG. 7 is a sectional view of the essential part of the semiconductor device in a manufacturing step next to the step of FIG. 6;

FIG. 8 is a sectional view of the essential part of the semiconductor device in a manufacturing step next to the step of FIG. 7;

FIG. 9 is a sectional view of the essential part of the semiconductor device in a manufacturing step next to the step of FIG. 8;

FIG. 10 is a sectional view of the essential part of the semiconductor device in a manufacturing step next to the step of FIG. 9;

FIG. 11 is a sectional view of the essential part of the semiconductor device in the same manufacturing step as the step of FIG. 10;

FIG. 12 is a sectional view of the essential part of the semiconductor device in a manufacturing step next to the step of FIG. 11;

FIG. 13 is a sectional view of the essential part of the semiconductor device in a manufacturing step next to the step of FIG. 12;

FIG. 14 is a sectional view of the essential part of the semiconductor device in a manufacturing step next to the step of FIG. 13;

FIG. 15 is a sectional view of the essential part of the semiconductor device in a manufacturing step next to the step of FIG. 14;

FIG. 16 is a sectional view of the essential part of the semiconductor device in a manufacturing step next to the step of FIG. 15;

FIG. 17 is a sectional view of the essential part of the semiconductor device in a manufacturing step next to the step of FIG. 16;

FIG. 18 is a sectional view of the essential part of the semiconductor device in a manufacturing step next to the step of FIG. 17;

FIG. 19 is a sectional view of the essential part of the semiconductor device in a manufacturing step next to the step of FIG. 18;

FIG. 20 is a sectional view of the essential part of the semiconductor device in a manufacturing step next to the step of FIG. 19;

FIG. 21 is a sectional view of the essential part of the semiconductor device in a manufacturing step next to the step of FIG. 20;

FIG. 22 is a sectional view of the essential part of the semiconductor device in a manufacturing step next to the step of FIG. 21;

FIG. 23 is a sectional view of the essential part of the semiconductor device in a manufacturing step next to the step of FIG. 22;

FIG. 24 is a sectional view of the essential part of the semiconductor device in a manufacturing step next to the step of FIG. 23;

FIG. 25 is a sectional view of an essential part of a semiconductor device as a comparative example;

FIG. 26 is a sectional view of an essential part of a semiconductor device according to a second embodiment of the invention;

FIG. 27 is a plan view of the essential part of the semiconductor device according to the second embodiment;

FIG. 28 is a sectional view of the essential part of the semiconductor device in a manufacturing step according to the second embodiment;

FIG. 29 is a sectional view of the essential part of the semiconductor device in a manufacturing step next to the step of FIG. 28;

FIG. 30 is a sectional view of an essential part of a semiconductor device according to a third embodiment of the invention;

FIG. 31 is a plan view of the essential part of the semiconductor device according to the third embodiment;

FIG. 32 is a sectional view of the essential part of the semiconductor device in a manufacturing step according to the third embodiment;

FIG. 33 is a sectional view of the essential part of the semiconductor device in a manufacturing step next to the step of FIG. 32;

FIG. 34 is a sectional view of the essential part of the semiconductor device in a manufacturing step next to the step of FIG. 33;

FIG. 35 is a sectional view of the essential part of the semiconductor device in a manufacturing step next to the step of FIG. 34;

FIG. 36 is a sectional view of an essential part of the semiconductor device according to a fourth embodiment of the invention;

FIG. 37 is a plan view of the essential part of the semiconductor device according to the fourth embodiment;

FIG. 38 is a sectional view of an essential part of a semiconductor device in a manufacturing step according to a fifth embodiment of the invention;

FIG. 39 is a sectional view of the essential part of the semiconductor device in a manufacturing step next to the step of FIG. 38;

FIG. 40 is a sectional view of the essential part of the semiconductor device in a manufacturing step next to the step of FIG. 39;

FIG. 41 is a sectional view of the essential part pf the semiconductor device in the same manufacturing step as the step of FIG. 40;

FIG. 42 is a sectional view of the essential part of the semiconductor device in a manufacturing step next to the step of FIG. 41;

FIG. 43 is a sectional view of the essential part of the semiconductor device in a manufacturing step next to the step of FIG. 42;

FIG. 44 is a sectional view of the essential part of the semiconductor device in a manufacturing step next to the step of FIG. 43; and

FIG. 45 is a sectional view of the essential part of the semiconductor device in a manufacturing step next to the step of FIG. 44.

### DETAILED DESCRIPTION

The preferred embodiments will be described below in different sections or separately as necessary, but such descriptions are not irrelevant to each other unless specified explicitly. One description may be, in whole or in part, a modified, detailed or supplementary form of another. Also, regarding the preferred embodiments described below, when a specific number (the number of pieces, numerical value, quantity, range, etc.) is indicated for an element, it is not limited to the specific number unless specified explicitly or theoretically limited to that number; it may be larger or smaller than the specific number. Furthermore, in the preferred embodiments described below, constituent elements (including constituent steps) are not necessarily essential unless specified explicitly or theoretically essential. Similarly, in the preferred embodiments described below, when a specific form or positional relation is indicated for an element, it should be interpreted to include a form or positional relation which is virtually equivalent or similar to the specific form or positional relation unless specified explicitly or theoretically limited to the specific form or positional relation. The same can be said of the above numerical data and ranges.

Next, the preferred embodiments will be described in detail referring to the accompanying drawings. In all the drawings that illustrate the preferred embodiments, elements with like functions are designated by like reference numerals and repeated descriptions thereof are omitted. Regarding the preferred embodiments below, basically descriptions of the same or similar elements are not repeated except when necessary.

In the drawings that illustrate the preferred embodiments, hatching may be omitted even in a sectional view for easy understanding and hatching may be used even in plan view for easy understanding.

### First Embodiment

### Structure of the Semiconductor Device

The semiconductor device according to the first embodiment is a semiconductor device having a MIM (Metal Insulator Metal) capacitor. Since a MIM capacitor can be formed over an interlayer insulating film over a semiconductor substrate, various elements (for example, a transistor) can be formed under the capacitor. This is advantageous in decreasing the chip area.

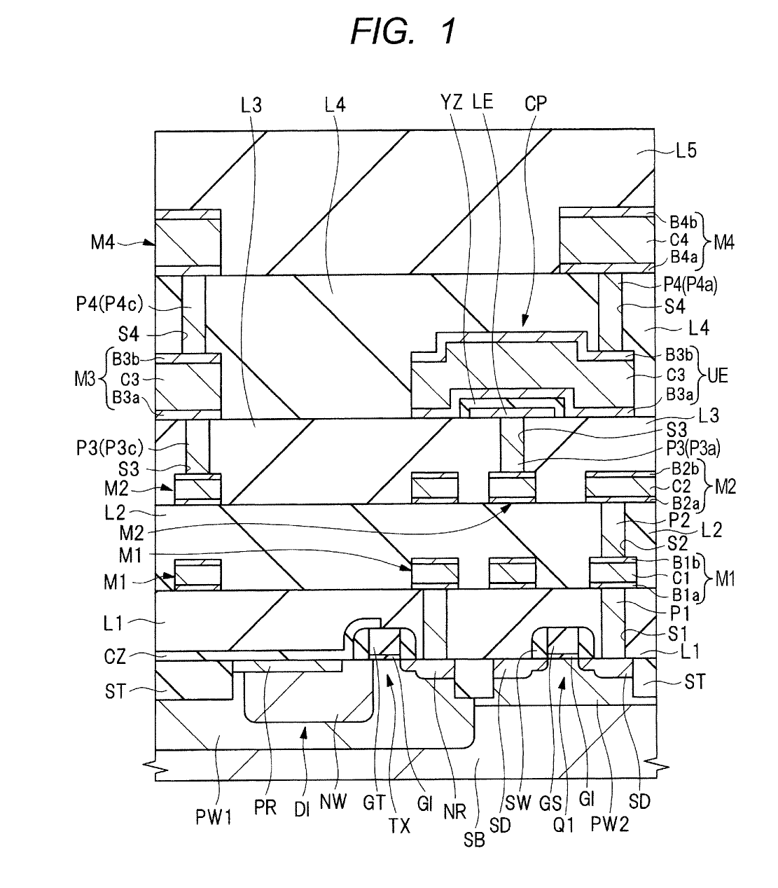

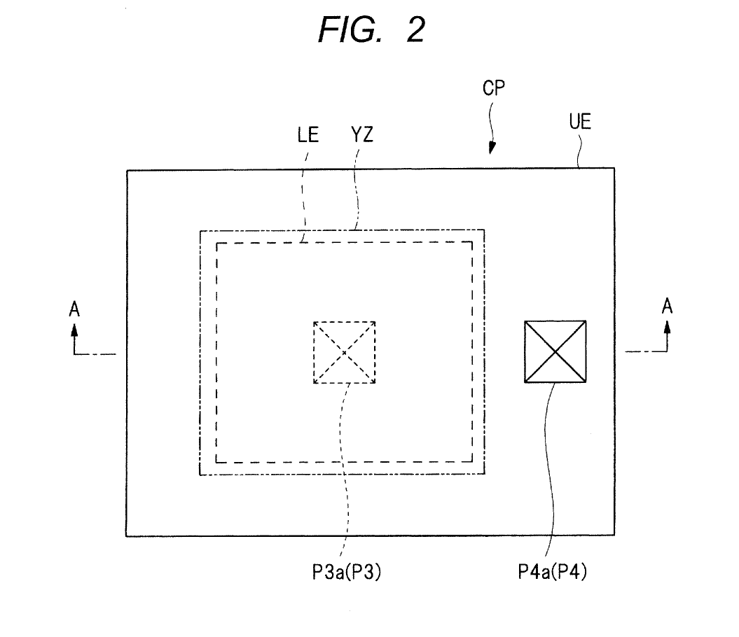

The structure of the semiconductor device according to this embodiment will be described referring to FIGS. 1 and 2.

FIG. 1 is a sectional view of an essential part of the semiconductor device according to this embodiment. FIG. 1 shows an example that the semiconductor device is a CMOS image sensor. Therefore, actually a plurality of pixels including a photodiode DI and transistors are arranged in an array pattern in the main surface of a semiconductor substrate SB, but FIG. 1 only shows a photodiode DI, a transfer transistor TX, and a pixel transistor Q1 as representative elements of one pixel.

FIG. 2 is a plan view of the essential part of the semiconductor device according to this embodiment. FIG. 2 is a plan view (planar layout) of a capacitor CP, showing a lower electrode LE, a capacitive insulating film YZ, and an upper electrode UE which constitute the capacitor CP. For easy understanding, the lower electrode LE, capacitive insulating film YZ and upper electrode UE are indicated by dotted line, chain double-dashed line, and solid line, respectively. FIG. 2 also shows a plug P3a coupled to the lower electrode LE and a plug P4a coupled to the upper electrode UE, in which the plug P3a and the plug P4a are indicated by dotted line and solid line, respectively. FIG. 1 shows a cross section of the capacitor CP which almost corresponds to the cross section taken along the line A-A of FIG. 2.

Here, a description is given of a case in which a plurality of pixels constituting a CMOS image sensor are formed in the main surface of the semiconductor substrate SB. However, the invention is not limited thereto and other various types of elements or circuits may be formed in the main surface of the semiconductor substrate SB and any element or circuit may be formed in the main surface of the semiconductor substrate SB.

As shown in FIG. 1, a photodiode DI, transfer transistor TX, and pixel transistor Q1 are formed in an active region of the main surface of the semiconductor substrate SB which is defined by element separation regions ST. The photodiode DI includes a p-type well PW1, n-type semiconductor region (n-type well), and p⁺-type semiconductor region PR.

The transfer transistor TX transfers electric charge generated by the photodiode DI. One pixel has a plurality of transistors including a transfer transistor TX. Here, the pixel transistor Q1 is shown to represent transistors other than the transfer transistor TX among the transistors which constitute the pixel.

The semiconductor substrate SB is, for example, a semiconductor substrate (semiconductor wafer) of n-type monocrystalline silicon doped with n-type impurities (donor) such as phosphor (P) or arsenic (As). Alternatively, the semiconductor substrate SB may be a so-called epitaxial wafer.

The element separation regions ST made of insulator are formed in the main surface of the semiconductor substrate SB to define the active region.

The p-type wells (p-type semiconductor regions) PW1 and PW2 extend to given depths from the main surface of the semiconductor substrate SB. The p-type well PW1 lies across the region in which the photodiode DI lies and the region in which the transfer transistor TX lies. The p-type well PW2 lies in the region in which the pixel transistor Q1 lies.

In the semiconductor substrate SB, the n-type semiconductor region (n-type well) NW is formed in a way to be contained in the p-type well PW1. The n-type semiconductor region NW is used to form the photodiode DI but it is also used to form the source region of the transfer transistor TX.

The p⁺-type semiconductor region PR lies in part of the surface of the n-type semiconductor region NW. The doping concentration of the p⁺-type semiconductor region PR (p-type doping concentration) is higher than the doping concentration of the p-type well PW1 (p-type doping concentration).

The bottom depth of the p⁺-type semiconductor region PR is smaller than the bottom depth of the n-type semiconductor region NW and the p⁺-type semiconductor region PR mostly lies in the surface layer of the n-type semiconductor region NW. Thus, when seen in the thickness direction of the semiconductor substrate SB, the n-type semiconductor region NW lies under the p⁺-type semiconductor region PR in the uppermost layer, and the p-type well PW1 lies under the n-type semiconductor region NW. In a region in which the n-type semiconductor region NW does not lie, part of the p⁺-type semiconductor region PR is in contact with the p-type well PW1.

A PN junction is made between the p-type well PW1 and the n-type semiconductor region NW. Also, a PN junction is made between the p⁺-type semiconductor region PR and the n-type semiconductor region NW. The p-type well PW1, n-type semiconductor region NW, and p⁺-type semiconductor region PR make up the photodiode (PN junction diode) DI.

The p⁺-type semiconductor region PR is intended to suppress generation of electrons based on many interface states formed on the surface of the semiconductor substrate SB. By forming the p⁺-type semiconductor region PR with holes as majority carriers in the surface of the n-type semiconductor region NW with electrons as majority carriers, generation of electrons without light radiation is suppressed to prevent an increase in dark current.

The photodiode DI is a photodetector (photoelectric transducer) which has a function to convert received light into electricity to generate charge and accumulate the charge, and the transfer transistor TX functions as a switch to transfer the charge accumulated in the photodiode DI from the photodiode.

The gate electrode GT of the transfer transistor TX is formed so as to partially overlap the n-type semiconductor region NW in plan view. The gate electrode GT lies over the semiconductor substrate SB through a gate insulating film GI. A sidewall spacer SW is formed as a sidewall insulating film over the sidewall of the gate electrode GT.

In the p-type well PW1 of the semiconductor substrate SB, the n-type semiconductor region NW is formed on one side of the gate electrode GT and an n-type semiconductor region NR is formed on the other side of the gate electrode GT. The n-type semiconductor region NR may have an LDD (Lightly Doped Drain) structure.

The n-type semiconductor region NR functions as the drain region of the transfer transistor TX and also it may be considered as a floating diffusion layer. The n-type semiconductor region NW is a constituent element of the photodiode DI and it can also function as a semiconductor region for the source of the transfer transistor TX. The n-type semiconductor region NW and the n-type semiconductor region NR are spaced from each other with the channel formation region of the transfer transistor TX between them.

A cap insulating film CZ is formed as a protective film over the surface of the photodiode DI, namely the surfaces of the n-type semiconductor region NW and p⁺-type semiconductor region PR. The cap insulating film CZ may partially lie over the gate electrode GT.

On the other hand, a gate electrode GS of the pixel transistor Q1 is formed over the p-type well PW2 of the semiconductor substrate SB through a gate insulating film GI. Sidewall spacers SW are formed as sidewall insulating films over the sidewalls on the both sides of the gate electrode GS. Also, source/drain regions SD of the pixel transistor Q1 are formed in the p-type well PW2 on the both sides of the gate electrode GS. The source/drain regions of the pixel transistor Q1 have an LDD structure.

A metal silicide layer (not shown) may be formed on the top of each of the n-type semiconductor region NR, source/drain regions SD, gate electrode GT and gate electrode GS by the so-called salicide (self-aligned silicide) process.

An interlayer insulating film L1 is formed over the semiconductor substrate SB so as to cover the gate electrodes GT and GS, cap insulating film CZ and sidewall spacers SW. The interlayer insulating film L1 lies over the whole main surface of the semiconductor substrate SB. The interlayer insulating film L1 and the interlayer insulating films L2, L3, L4, and L5, which will be described later, are silicon oxide films, for example, silicon oxide films made of TEOS (Tetra Ethyl Ortho Silicate). Instead, they may be HDP oxide films. An HDP oxide film is a silicon oxide film made by the HDP (High Density Plasma)-CVD method.

A through hole as a contact hole (opening, through hole) S1 is made in the interlayer insulating film L1 and a conductive plug (contact plug) P1 as a conductor for coupling is formed in the through hole S1.

The through hole S1 and the plug P1 buried therein are formed, for example, over the n-type semiconductor region NR, source/drain region SD, gate electrode GT or gate electrode GS.

A multilayer wiring structure including a plurality of wiring layers is formed over the interlayer insulating film L1. In this example, first to fourth wiring layers, four wiring layers in total, are formed. However, the number of wiring layers is not limited to four but it may be changed arbitrarily. The wiring in the first wiring layer as the lowermost wiring layer is wiring M1; the wiring in the second wiring layer as the layer just above the first wiring layer is wiring M2; the wiring in the third wiring layer as the layer just above the second wiring layer is wiring M3; and the wiring in the fourth wiring layer as the layer just above the third wiring layer is wiring M4. In the example shown in FIG. 1, the fourth wiring layer is the uppermost layer but another wiring layer may be made above the fourth wiring layer.

The wiring M1 in the first wiring layer lies over the interlayer insulating film L1 in which the plug P1 is buried. The plug P1 is electrically coupled to the wiring M1 with its upper surface abutting on the bottom of the wiring M1.

An interlayer insulating film L2 is formed over the interlayer insulating film L1 so as to cover the wiring M1. A through hole (opening, through hole) S2 is made in the interlayer insulating film L2 and a conductive plug (contact plug) P2 as a conductor for coupling is formed in the through hole S2.

The wiring M2 in the second wiring layer lies over the interlayer insulating film L2 in which the plug P2 is buried.

An interlayer insulating film L3 is formed over the interlayer insulating film L2 so as to cover the wiring M2. A through hole (opening, through hole) S3 is made in the interlayer insulating film L3 and a conductive plug (contact plug) P3 as a conductor for coupling is formed in the through hole S3.

The wiring M3 in the third wiring layer lies over the interlayer insulating film L3 in which the plug P3 is buried.

An interlayer insulating film L4 is formed over the interlayer insulating film L3 so as to cover the wiring M3. A through hole (opening, through hole) S4 is made in the interlayer insulating film L4 and a conductive plug (contact plug) P4 as a conductor for coupling is made in the through hole S4.

The wiring M4 in the fourth wiring layer lies over the interlayer insulating film L4 in which the plug P4 is buried.

An interlayer insulating film L5 is formed over the interlayer insulating film L4 so as to cover the wiring M4. In the case of a CMOS image sensor, a color filter (not shown) or micro-lens (not shown) may be located over the interlayer insulating film L5. Also, a passivation film (not shown) may be formed over the interlayer insulating film L5. A pad (bonding pad) may be formed by making an opening in the interlayer insulating film L5 and having the wiring M5 partially exposed from the opening.

The wiring M1 in the first wiring layer is a patterned conductive film (laminated conductive film) and in this example, it includes a barrier conductive film B1a, main conductive film C1, and barrier conductive film B1b which are stacked from bottom up. The wiring M2 in the second wiring layer is a patterned conductive film (laminated conductive film) and in this example, it includes a barrier conductive film B2a, main conductive film C2, and barrier conductive film B2b which are stacked from bottom up. The wiring M3 in the third wiring layer is a patterned conductive film (laminated conductive film) and in this example, it includes a barrier conductive film B3a, main conductive film C3, and barrier conductive film B3b which are stacked from bottom up. The wiring M4 in the fourth wiring layer is a patterned conductive film (laminated conductive film) and in this example, it includes a barrier conductive film B4a, main conductive film C4, and barrier conductive film B4b which are stacked from bottom up.

In the wiring layers, preferably the lower barrier conductive films (B1a, B2a, B3a, B4a) of the wirings (M1 to M4) are titanium nitride (TiN) films, but alternatively they may be titanium (Ti) films or laminated films of titanium (Ti) and titanium nitride (TiN) films. The lower barrier conductive films (B1a, B2a, B3a, B4a) have a function to increase the adhesion between the wirings (M1, M2, M3, M4) and the underlying insulating films (L1, L2, L3, L4).

In the wiring layers, preferably the upper barrier conductive films (B1b, B2b, B3b, B4b) of the wirings (M1, M2, M3, M4) are titanium nitride (TiN) films, but alternatively they may be titanium (Ti) films or laminated films of titanium (Ti) and titanium nitride (TiN) films. The upper barrier conductive films (B1b, B2b, B3b, B4b) have a function to increase the adhesion between the wirings (M1, M2, M3, M4) and the insulating insulating films (L2, L3, L4, L5) covering the wirings (M1, M2, M3, M4) and also function as antireflection films in the photolithographic process.

The wirings M1, M2, M3, and M4 are all aluminum wirings which contain aluminum (Al) as a main component, or aluminum-based wirings. This means that the main conductive films C1, C2, C3, and C4 are aluminum (Al)-based conductive films (films of conducting material with metal conductivity). Whereas the main conductive films C1, C2, C3, and C4 may be aluminum films, they are not limited thereto and for example, they may be compound or alloy films of Al (aluminum) and Si (silicon) or compound or alloy films of Al (aluminum) and Cu (copper), or compound or alloy films of Al (aluminum), Si (silicon), and Cu (copper) as appropriate. The composition ratio of Al (aluminum) of each of the main conductive films C1, C2, C3, and C4 should be more than 50 atom percent (namely Al-rich), more preferably 99 atom percent or more.

The thickness of the main conductive film (C1 to C4) of each of the wirings M1 to M4 is larger than the thickness of the lower barrier conductive film (B1a to B4a) and larger than the thickness of the upper barrier conductive film (B1b to B4b).

The plugs P1, P2, P3, and P4 are all contact plugs. The plugs P1, P2, P3, and P4 can be considered as conductors for coupling which are buried in the interlayer insulating films (buried conductors). Each of the plugs P1, P2, P3, and P4 includes a thin barrier conductive film formed over the bottom and sidewalls (side faces) of the through hole (S1 to S4) and a main conductive film formed over the barrier conductive film and buried in the trough hole (S1 to S4). For illustrative simplicity, FIG. 1 shows the barrier conductive films and main conductive films of the plugs P1, P2, P3, and P4 as integrated with each other. The barrier conductive films of the plugs P1, P2, P3, and P4 may be titanium films, titanium nitride films or laminated films of titanium and titanium nitride films. The main conductive films of the plugs P1, P2, P3, and P4 may be tungsten films. Alternatively, a material other than tungsten, for example, copper may be used for any of the plugs P1, P2, P3, and P4.

The plug P2 is located between the wirings M2 and M1. The upper surface of the plug P2 abuts on the lower surface of the wiring M2 so that the plug P2 and wiring M2 are electrically coupled, and the lower surface of the plug P2 abuts on the upper surface of the wiring M1 so that the plug P2 and wiring M1 are electrically coupled. Thus, the plug P2 electrically couples the wiring M2 overlying the plug P2 and the wiring M1 underlying the plug P2.

The plug 3 is located between the wirings M3 and M2 or between the lower electrode LE and wiring M2. The upper surface of the plug P3 abuts on the lower surface of the wiring M3 or the lower surface of the lower electrode LE so that the plug P3 and the wiring M3 or the lower electrode LE are electrically coupled, and the lower surface of the plug P3 abuts on the upper surface of the wiring M2 so that the plug P3 and the wiring M2 are electrically coupled. Thus, the plug P3 electrically couples the wiring M3 or lower electrode LE overlying the plug P3 and the wiring M2 underlying the lower electrode LE and plug P3.

The plug 4 is located between the wirings M4 and M3 or between the wiring M4 and the upper electrode UE. The upper surface of the plug P4 abuts on the lower surface of the wiring M4 so that the plug P4 and wiring M4 are electrically coupled, and the lower surface of the plug P4 abuts on the upper surface of the wiring M3 or the upper surface of the upper electrode UE so that the plug P4 and the wiring M3 or the upper electrode UE are electrically coupled. Thus, the plug P4 electrically couples the wiring M4 overlying the plug P4 and the wiring M3 or upper electrode UE underlying the plug P4.

In this embodiment, a MIM capacitor CP is formed in a wiring layer of the multilayer wiring structure formed over the semiconductor substrate SB. In the example shown in FIG. 1, a capacitor CP is formed in the third wiring layer.

The capacitor CP includes a lower electrode (first electrode) LE, an upper electrode (second electrode) UE, and a capacitive insulating film (dielectric film) YZ interposed between the lower electrode LE and upper electrode UE.

The lower electrode LE of the capacitor CP lies over the interlayer insulating film 3 in which the plug P3 is buried. The lower electrode LE is a conductive film (film of conducting material with metal conductivity) and preferably the material of the film has a higher melting point than aluminum (Al). It may be a titanium nitride (TiN) film, titanium (Ti) film, tantalum nitride (TaN) film or tantalum (Ta) film as appropriate. In this example, a titanium nitride (TiN) film is used for the lower electrode LE.

A plug P3 is located under the lower electrode LE and electrically coupled to the lower electrode LE. Here, among the plugs P3, the plug P3 located under the lower electrode LE and electrically coupled to the lower electrode LE is designated by sign P3a and hereinafter called plug P3a. The upper surface of the plug P3a abuts on the lower surface of the lower electrode LE so that the plug P3a and the lower electrode LE are electrically coupled. Also, among the plugs P3, the plug P3 located under the wiring M3 and electrically coupled to the wiring M3 is designated by sign P3c and hereinafter called plug P3c. The upper surface of the plug P3c abuts on the lower surface of the wiring M3 so that the plug P3c and the wiring M3 are electrically coupled.

Whereas the plug P3a (plug P3a coupled to the lower electrode LE) is located under the lower electrode LE, the plug P4 (plug P4 coupled to the lower electrode LE) is not located over the lower electrode LE.

The plug P3c, located between the wirings M3 and M2, functions to couple the wirings M3 and M2 electrically. On the other hand, the plug P3a, located under the lower electrode LE, functions to electrically couple the lower electrode LE and the wiring M2 underlying the plug P3a. In other words, the plug P3a is located between the lower electrode LE and the wiring M2 and the upper surface of the plug P3a abuts on the lower surface of the lower electrode LE so that the plug P3a and the lower electrode LE are electrically coupled, and the lower surface of the plug P3a abuts on the upper surface of the wiring M2 so that the plug P3a and the wiring M2 are electrically coupled. Thus, the plug P3a electrically couples the lower electrode LE overlying the plug P3a and the wiring M2 underlying the plug P3a.

The capacitive insulating film YZ lies over the interlayer insulating film L3 so as to cover the lower electrode LE. The capacitive insulating film YZ is, for example, a silicon nitride film. As can be known from FIG. 2, the lower electrode LE is contained in the capacitive insulating film YZ in plan view. Specifically the upper surface and side surfaces of the lower electrode LE are covered by the capacitive insulating film YZ. Thus, the capacitive insulating film lies between the lower electrode LE and upper electrode UE and the lower electrode LE and upper electrode UE are not in contact with each other. The lower surface (bottom) of the lower electrode LE, except its portion facing the upper surface of the plug P3a, faces the upper surface of the interlayer insulating film L3. In other words, the lower surface (bottom) of the lower electrode LE abuts on the upper surface of the interlayer insulating film L3 except its portion abutting on the upper surface of the plug P3a.

The upper electrode UE lies over the interlayer insulating film L3 so as to cover the capacitive insulating film YZ (thus, so as to cover the lower electrode LE as well). The upper electrode UE is formed in the same layer in which the wiring M3 in the third wiring layer is formed. In other words, the upper electrode UE is formed from the conductive film pattern in the same layer as the wiring M3 in the third wiring layer. Specifically, the upper electrode UE and wiring M3 are formed by patterning the same conductive film (which corresponds to a conductive film CD3 which will be described later). The upper electrode UE and wiring M3 are not joined but separated from each other. A portion of the upper electrode UE may extend over the interlayer insulating film L3 and function as a wiring.

The material of the upper electrode UE is the same as the material of the wiring M3. The thickness of the upper electrode UE is virtually equal to the thickness of the wiring M3. The difference between the thickness of the upper electrode UE and the thickness of the wiring M3 is within the range of variation in the thickness of the conductive film CD3 (described later). The lamination structure of the upper electrode UE is the same as the lamination structure of the wiring M3.

In other words, when the wiring M3 is a laminated film including a barrier conductive film B3a, a main conductive film C3 overlying the barrier conductive film B3a, and a barrier conductive film B3b overlying the main conductive film C3, the upper electrode UE is also a laminated film including a barrier conductive film 3a, a main conductive film C3 overlying the barrier conductive film B3a and a barrier conductive film B3b overlying the main conductive film C3. The barrier conductive film B3a of the upper electrode UE and the barrier conductive film B3a of the wiring M3 are made of the same material and have virtually the same thickness. Also, the main conductive film C3 of the upper electrode UE and the main conductive film C3 of the wiring M3 are made of the same material and have virtually the same thickness. Also, the barrier conductive film B3b of the upper electrode UE and the barrier conductive film B3b of the wiring M3 are made of the same material and have virtually the same thickness.

As can be known from FIG. 2, the upper electrode UE contains the capacitive insulating film YZ and lower electrode LE in plan view. Thus, in plan view, the lower electrode LE is contained in the capacitive insulating film YZ and the capacitive insulating film YZ is contained in the upper electrode UE. Specifically, in plan view, the capacitive insulating film YZ has a portion overlapping the lower electrode LE and a portion not overlapping it and the peripheral portion of the capacitive insulating film YZ does not overlap the lower electrode LE; and the upper electrode UE has a portion overlapping the capacitive insulating film YZ and a portion not overlapping it and the peripheral portion of the upper electrode UE does not overlap the capacitive insulating film YZ. Therefore, the planar size (planar area) of the capacitive insulating film YZ is larger than the planar size (planar area) of the lower electrode LE, and the planar size (planar area) of the upper electrode UE is larger than the planar size (planar area) of the capacitive insulating film YZ.

The expression “in plan view” or “when viewed planarly” means that an object is seen on a plane parallel to the main surface of the semiconductor substrate SB.

A plug P4 is located over the upper electrode UE and electrically coupled to the upper electrode UE. Here, among the plugs P4, the plug P4 located over the upper electrode UE and electrically coupled to the upper electrode UE is designated by sign P4a and hereinafter called plug P4a. The lower surface (bottom) of the plug P4a abuts on the upper surface of the upper electrode UE so that the plug P4a and the upper electrode UE are electrically coupled. Among the plugs P4, the plug P4 located over the wiring M3 and electrically coupled to the wiring M3 is designated by sign P4c and hereinafter called plug P4c. The lower surface (bottom) of the plug P4c abuts on the upper surface of the wiring M3 so that the plug P4c and wiring M3 are electrically coupled.

The plug P4a, located over the upper electrode UE and electrically coupled to the upper electrode UE, does not overlap the lower electrode LE in plan view. In other words, in plan view, the plug P4a is located so as to overlap the upper electrode UE but not to overlap the lower electrode LE. Specifically, the upper electrode UE has a portion overlapping the lower electrode LE and a portion not overlapping the lower electrode LE and in plan view and the plug P4a is located over the upper electrode UE's portion not overlapping the lower electrode LE.

The plug P4a, located over the upper electrode UE and electrically coupled to the upper electrode UE, does not overlap the capacitive insulating film YZ in plan view. In other words, in plan view, the plug P4a is located so as to overlap the upper electrode UE but not to overlap the capacitive insulating film YZ. Specifically, the upper electrode UE has a portion overlapping the capacitive insulating film YZ and a portion not overlapping the capacitive insulating film YZ and in plan view and the plug P4a is located over the upper electrode UE's portion not overlapping the capacitive insulating film YZ.

Therefore, in plan view, the plug P4a neither overlaps the lower electrode LE nor the capacitive insulating film YZ.

In plan view, while the plug P4a (plug P4a coupled to the upper electrode UE) is located over the upper electrode UE's portion not overlapping the lower electrode LE, the plug P4 (plug P4 coupled to the upper electrode UE) is not located over the upper electrode UE's portion overlapping the lower electrode LE.

The plug P4c, located between the wirings M4 and M3, functions to couple the wirings M4 and M3 electrically. On the other hand, the plug P4a, located over the upper electrode UE, functions to couple the upper electrode UE and the wiring M4 overlying the plug P4a electrically. In other words, the plug P4a is located between the wiring M4 and the upper electrode UE and the upper surface of the plug P4a abuts on the lower surface of the wiring M4 so that the plug P4a and the upper electrode UE are electrically coupled, and the lower surface of the plug P4a abuts on the upper surface of the upper electrode UE so that the plug P4a and the upper electrode UE are electrically coupled. Thus, the plug P4a electrically couples the upper electrode UE underlying the plug P4a and the wiring M4 overlying the plug P4a.

The height (h2) of the plug P4c located between the wirings M4 and M3 is almost equal to the height (h1) of the plug P4a located between the wiring M4 and upper electrode UE (h1=h2). From another point of view, the depth (d2) of a through hole S4 made (located) over the wiring M3, in which the plug P4c is buried, is almost equal to the depth (d1) of a through hole S4 made (located) over the upper electrode UE, in which the plug P4a is buried (d1=d2). This is because the upper electrode UE and wiring M3 are formed from the conductive film pattern in the same layer and thus the thickness of the upper electrode UE and the thickness of the wiring M3 are virtually equal and the plug P4a is formed (located) over the upper electrode UE's portion not overlapping the lower electrode LE and the capacitive insulating film YZ in plan view.

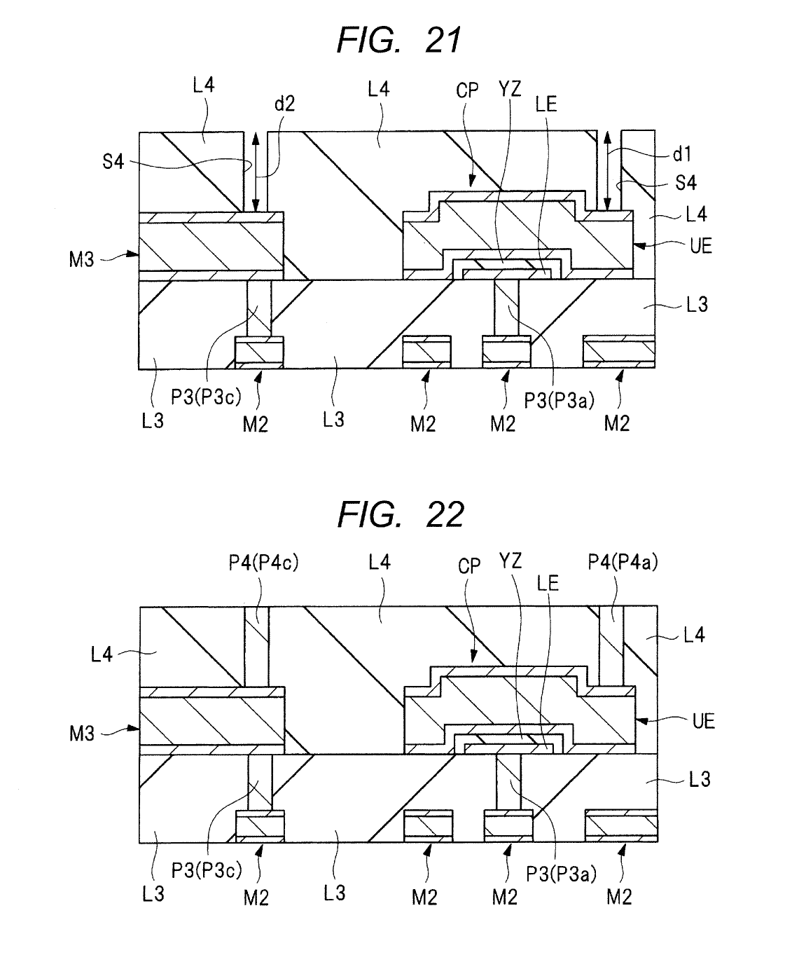

The height h1 of the plug P4a and the height h2 of the plug P4c are shown in FIG. 24 and the depth d1 of the through hole S4 in which the plug P4a is buried, and the depth d2 of the through hole S4 in which the plug P4c is buried are shown in FIG. 21. The height h1 of the plug P4a is almost equal to the depth d1 of the through hole S4 in which the plug P4a is buried and the height h2 of the plug P4c is almost equal to the depth d2 of the through hole S4 in which the plug P4c is buried.

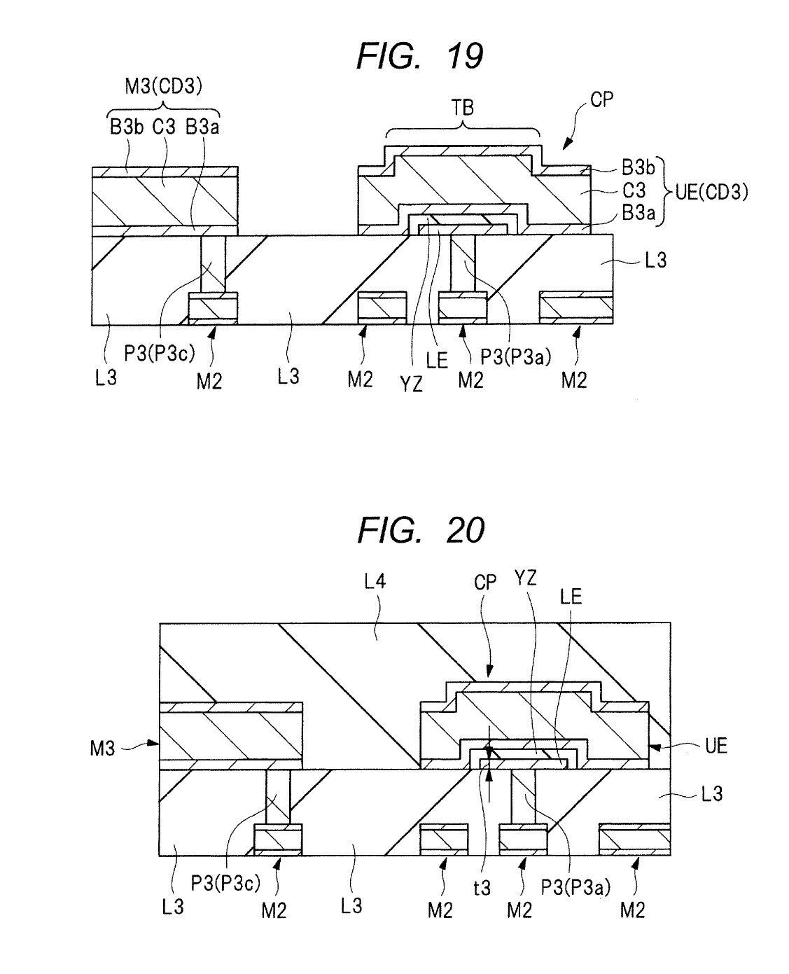

The upper surface of the upper electrode UE has a convex portion TB, which reflects the presence of the lower electrode LE and capacitive insulating film YZ under a portion of the upper electrode UE. The convex portion TB corresponds to the area designated by sign TB in FIG. 19. The convex portion TB is produced by having the upper surface of the upper electrode UE's portion overlying the lower electrode LE and capacitive insulating film YZ raised by the amount equivalent to the thicknesses of the lower electrode LE and capacitive insulating film YZ. On the upper surface of the upper electrode UE, the convex portion TB is higher than the area around the convex portion TB by the amount equivalent to the thicknesses of the lower electrode LE and capacitive insulating film YZ. In plan view, the area of the convex portion TB almost coincides with the area in which the lower electrode LE and the capacitive insulating film YZ are formed. In this embodiment and the second to fifth embodiments which will be described later, no plug P4 coupled to the upper electrode UE is located over the convex portion of the upper surface of the upper electrode UE which reflects the presence of the lower electrode LE and capacitive insulating film YZ.

In this embodiment and the third embodiment which will be described later, a plug P4a coupled to the upper electrode UE is located in the area around the convex portion TB of the upper surface of the upper electrode UE, namely the area lower than the convex portion TB. In the area around the convex portion TB of the upper surface of the upper electrode UE, namely the area lower than the convex portion TB, the top position of the upper surface of the upper electrode UE is almost the same as the top position of the upper surface of the wiring M3, so the height (h2) of the plug P4c overlying the wiring M3 is almost equal to the height (h1) of the plug P4a overlying the upper electrode UE (h1=h2).

### <Semiconductor Device Manufacturing Process>

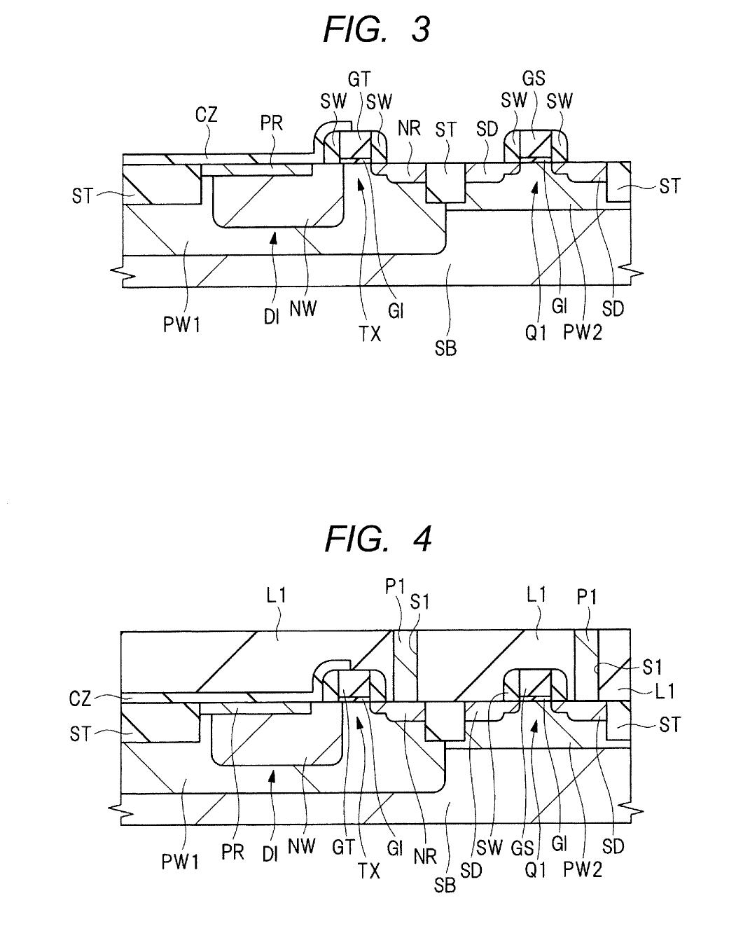

Next, the process of manufacturing the semiconductor device according to this embodiment will be described referring to drawings. FIGS. 3 to 24 are sectional views of the essential part of the semiconductor device in manufacturing steps according to this embodiment.

In order to manufacture the semiconductor device according to this embodiment, first a semiconductor substrate (semiconductor wafer) SB is provided as shown in FIG. 3.

The semiconductor substrate SB is, for example, a semiconductor substrate (semiconductor wafer) of n-type monocrystalline silicon, etc. which is doped with n-type impurities such as phosphor (P) or arsenic (As). Alternatively the semiconductor substrate SB may be the so-called epitaxial wafer.

Next, the following steps are taken to form semiconductor elements including a photodetector (photodiode DI in this example) with the semiconductor substrate SB.

First, as shown in FIG. 3, an element separation region ST as an insulator (insulator buried in a trench) is formed in the main surface of the semiconductor substrate SB by the STI (Shallow Trench Isolation) method or the like. Alternatively, the LOCOS (Local oxidation of silicon) method may be employed to form an element separation region ST. The active region of the semiconductor substrate SB is defined by element separation regions ST.

A p-type well PW1, p-type well PW2, n-type semiconductor region NR, and p⁺-type semiconductor region PR are formed by implanting ions into the semiconductor substrate SB. The p-type well PW1, n-type semiconductor region NR, and p⁺-type semiconductor region PR make up a photodiode (PN junction diode) DI.

Then, a gate electrode GT for a transfer transistor TX and a gate electrode GS for a pixel transistor Q1 are each formed over the semiconductor substrate SB through a gate insulating film GI.

Then, an n-type semiconductor region NR and source/drain regions SD are formed by implanting ions into the semiconductor substrate SB. Here, by forming an extension region with a low doping concentration by ion implantation and then forming a sidewall spacer SW before forming a high-doped region by ion implantation, the n-type semiconductor region NR and source/drain regions SD may each have an LDD structure with a low-doped extension region and a high-doped region.

Then, annealing (heat treatment) is done to activate the implanted impurity ions.

The photodiode DI, transfer transistor TX and pixel transistor Q1 are thus formed with the semiconductor substrate SB.

Then, a cap insulating film (protective film) CZ is formed by making an insulating film over the main surface of the semiconductor substrate SB and patterning the insulating film by photolithography or dry etching. For example, the cap insulating film CZ may be a silicon oxide film.

Then, a low-resistance metal silicide layer (not shown) may be formed over each of the n-type semiconductor region NR, source/drain regions SD, gate electrode GT, and gate electrode GS by the salicide technique.

Semiconductor elements including the photodetector (photodiode DI in this example) are formed with the semiconductor substrate SB as shown in FIG. 3 by the above steps. Although this embodiment assumes that semiconductor elements including a photodetector are formed with the semiconductor substrate SB, the invention is not limited thereto and other various types of elements may be formed with the semiconductor substrate SB. Semiconductor elements which do not include a photodetector may be formed with the semiconductor substrate SB.

Next, as shown in FIG. 4, an interlayer insulating film L1 is formed over the main surface of the semiconductor substrate SB. The interlayer insulating film L1 is formed so as to cover the gate electrodes GT and GS, sidewall spacers SW, and cap insulating film CZ.

The interlayer insulating film L1 is, for example, a silicon oxide film. For example, the silicon oxide film may be a silicon oxide film made of TEOS, which can be formed by the CVD method or it may be an HDP oxide film.

After the formation of the interlayer insulating film L1, the front surface (upper surface) of the interlayer insulating film L1 is planarized by polishing it by the CMP (Chemical Mechanical Polishing) method or the like. Even if, at the time of formation of the interlayer insulating film L1, its front surface is uneven due to an uneven underlying surface, it can be planarized by polishing it by the CMP method to obtain an interlayer insulating film L1 with a flat surface.

Then, through holes S1 are made in the interlayer insulating film L1 by etching (preferably dry-etching) the interlayer insulating film L1, using a photoresist pattern (not shown) made over the interlayer insulating film L1 by photolithography as an etching mask. The through holes S1 are made so as to penetrate the interlayer insulating film L1.

Then, a plug P1 is formed in a through hole S1. The plug P1 may be formed as follows.

First, a barrier conductive film (for example, titanium film, titanium nitride film or a laminated film of titanium and titanium nitride films) is formed over the interlayer insulating film L1 including the insides of the through holes S1 (bottom and sidewall), by sputtering or plasma CVD. Then, a main conductive film (for example, tungsten film) is formed over the barrier conductive film by CVD in a way to fill the through holes S1. Then, unwanted portions of the main conductive film and barrier conductive film outside the through holes S1 are removed by the CMP method or etching back. Consequently, the upper surface of the interlayer insulating film L1 is exposed and the barrier conductive film and main conductive film remaining buried in each through hole S1 make up a plug P1. In FIG. 4, for illustrative simplicity, the plug P1 is shown monolithically as an integration of the main conductive film and barrier conductive film.

Next, a wiring M1 in a first wiring layer is formed over the interlayer insulating film L1 in which the plugs P1 are buried. The wiring M1 may be formed as follows.

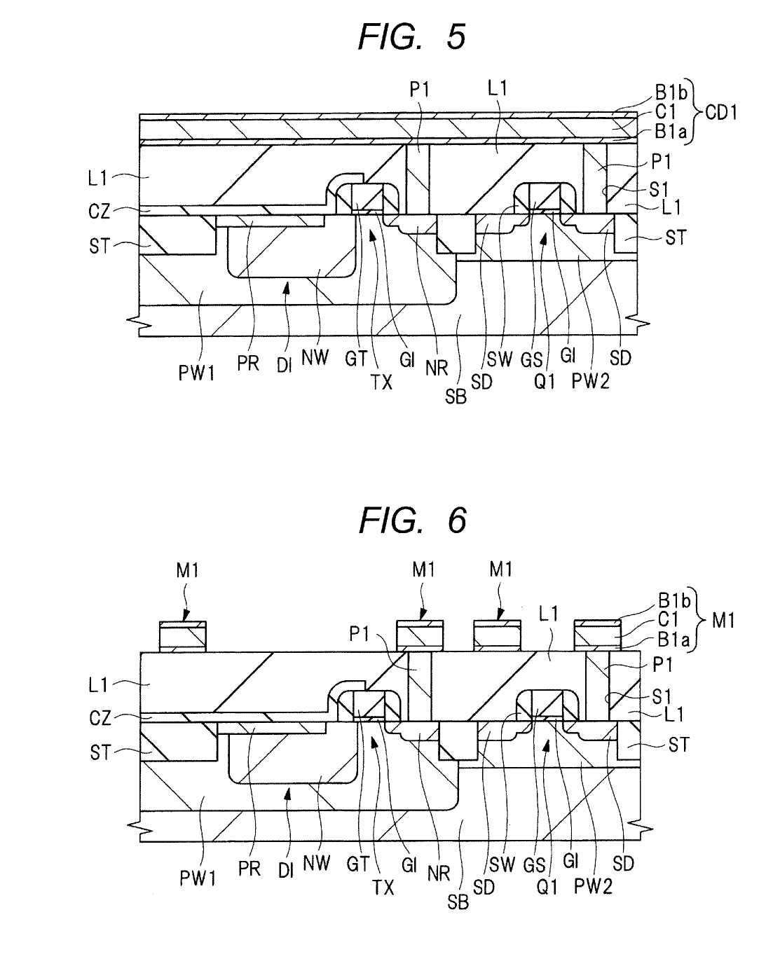

First, as shown in FIG. 5, a conductive film CD1 for the first wiring layer is formed over the interlayer insulating film L1 in which the plugs P1 are buried. The conductive film CD1 is a laminated film including a barrier conductive film B1a, a main conductive film C1 over the barrier conductive film B1a, and a barrier conductive film B1_{b} over the main conductive film C1 which are formed by sputtering or the like. The materials of the films are as mentioned above. Then, the wiring M1 as the patterned conductive film CD1 can be formed as shown in FIG. 6 by patterning the conductive film CD1 by photolithography or etching.

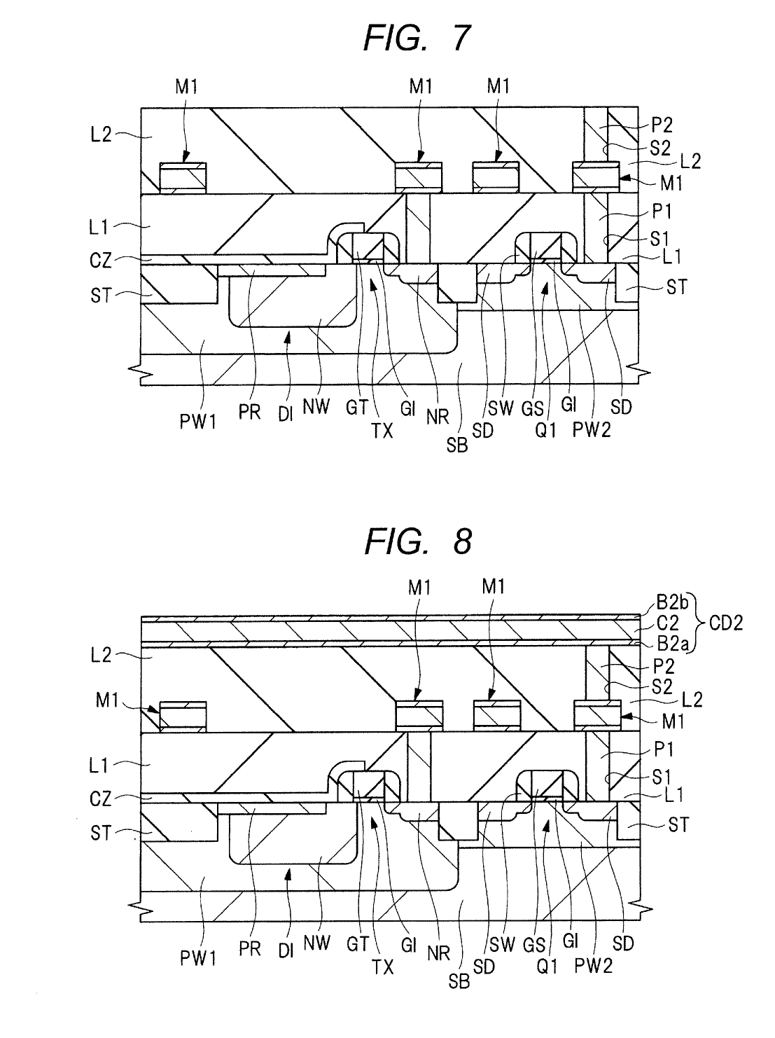

Then, as shown in FIG. 7, an interlayer insulating film L2 is formed over the main surface (whole main surface) of the semiconductor substrate SB, namely the interlayer insulating film L1, so as to cover the wiring M1. The interlayer insulating film L2 is, for example, a silicon oxide film. For example, the silicon oxide film may be a silicon oxide film made of TEOS which can be formed by the CVD method or it may be an HDP oxide film. After the formation of the interlayer insulating film L2, the planarity of the upper surface of the interlayer insulating film L2 may be increased by polishing it by the CMP method as necessary.

Then, a through hole S2 is made in the interlayer insulating film L2 by etching (preferably dry-etching) the interlayer insulating film L2 using a photoresist pattern (not shown) made over the interlayer insulating film L2 by photolithography as an etching mask. The through hole S2 penetrates the interlayer insulating film L2 and the upper surface of the wiring M1 is exposed at the bottom of the through hole S2.

Then, a plug P2 is formed in the through hole S2 by burying conductive film in the through hole S2. The plug P2 can be formed by a method similar to the method for forming the plug P1.

Next, a wiring M2 in a second wiring layer is formed over the interlayer insulating film L2 in which the plug P2 is buried. The wiring M2 may be formed as follows.

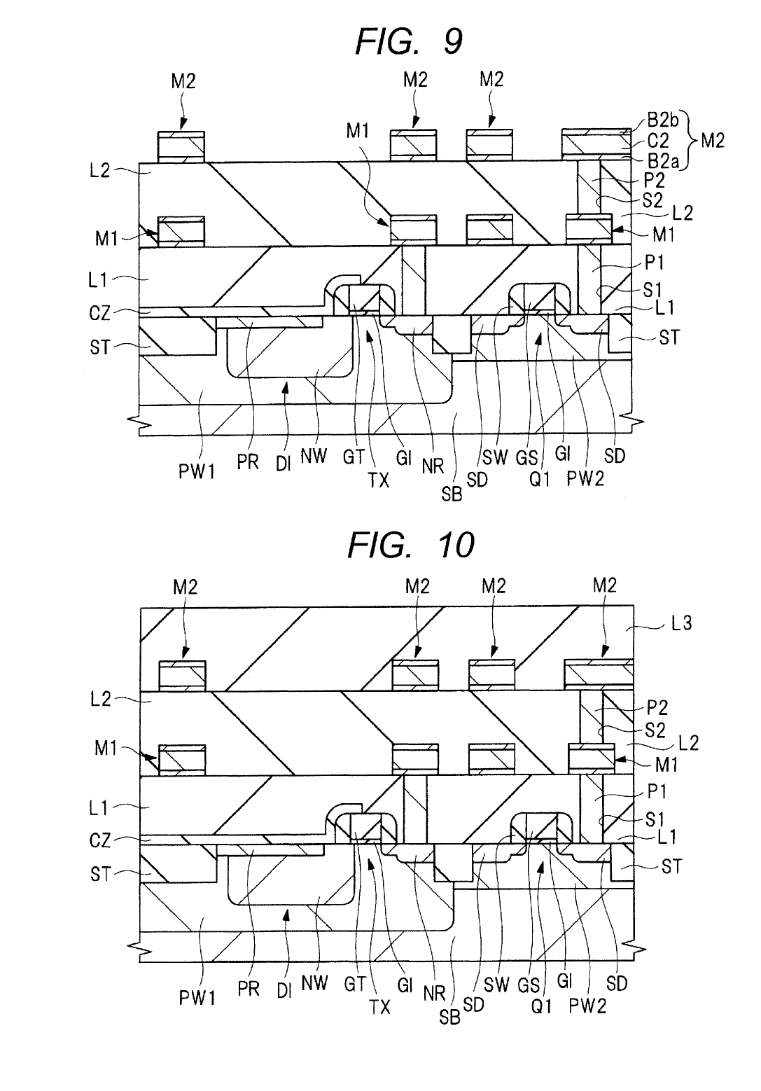

First, as shown in FIG. 8, a conductive film CD2 for the second wiring layer is formed over the interlayer insulating film L2 in which the plug P2 is buried. The conductive film CD2 is a laminated film including a barrier conductive film B2a, a main conductive film C2 over the barrier conductive film B2a, and a barrier conductive film B2b over the main conductive film C2 which are formed by sputtering or the like. The materials of the films are as mentioned above. Then, the wiring M2 is formed from the patterned conductive film CD2 as shown in FIG. 9 by patterning the conductive film CD2 by photolithography and etching.

Then, as shown in FIG. 10, an interlayer insulating film L3 is formed over the main surface (whole main surface) of the semiconductor substrate SB, namely the interlayer insulating film L2, so as to cover the wiring M2. The interlayer insulating film L3 is, for example, a silicon oxide film. For example, the silicon oxide film may be a silicon oxide film made of TEOS which can be formed by the CVD method or it may be an HDP oxide film. After the formation of the interlayer insulating film L3, the planarity of the upper surface of the interlayer insulating film L3 may be increased by polishing it by the CMP method as necessary. The structure as shown in FIG. 10 is thus obtained.

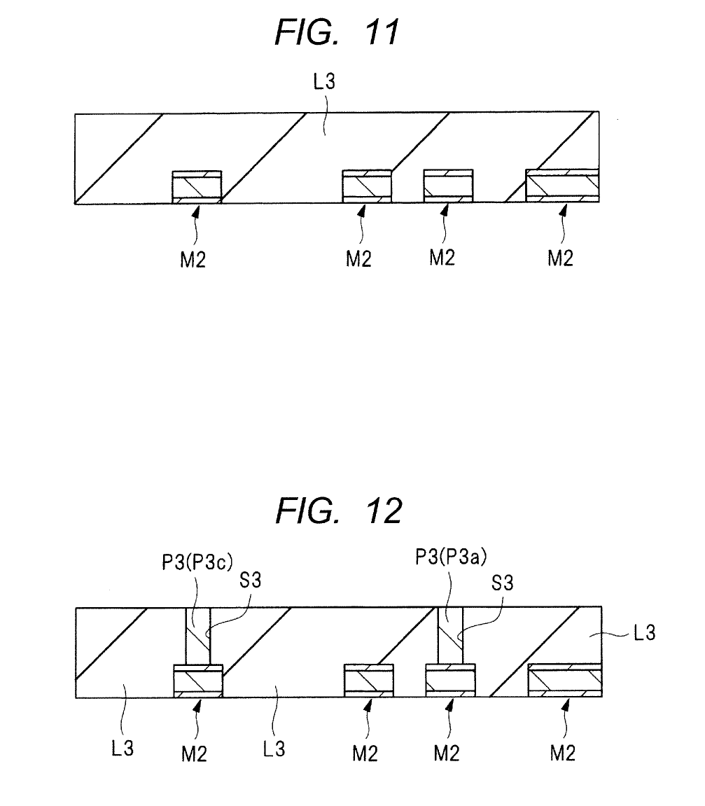

Although FIG. 11 shows the same step as FIG. 10, in FIGS. 11 to 24 the interlayer insulating film L2 and the layers under it are omitted for illustrative simplicity. Also, in FIG. 11, the intervals between wirings M2 are slightly different from those in FIG. 10 for illustrative convenience.

Then, as shown in FIG. 12, a through hole S3 is made in the interlayer insulating film L3 by etching (preferably dry-etching) the interlayer insulating film L3 using a photoresist pattern (not shown) made over the interlayer insulating film L3 by photolithography as an etching mask. The through hole S3 penetrates the interlayer insulating film L3 and the upper surface of the wiring M2 is exposed at the bottom of the through hole S3.

Then, a plug P3 is formed in each through hole S3 by burying conductive film in the through hole S3. The plug P3 can be formed by a method similar to the method for forming the plug P1.

Next, a lower electrode LE of a capacitor CP is formed over the interlayer insulating film L3 in which the plugs P3 are buried. The lower electrode LE may be formed as follows.

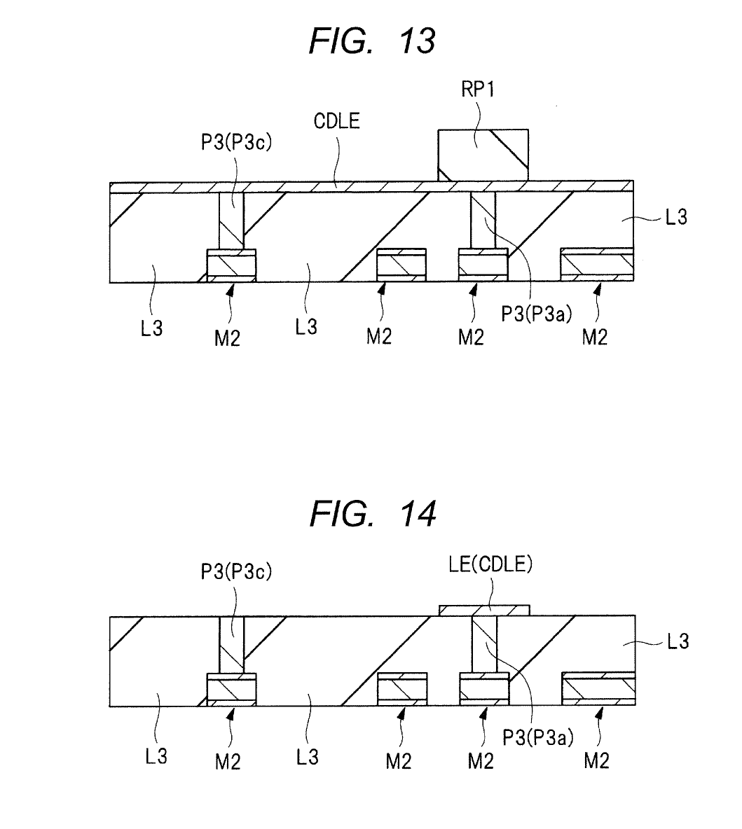

First, as shown in FIG. 13, a conductive film CDLE for the formation of the lower electrode LE is formed over the main surface (whole main surface) of the semiconductor substrate SB, namely the interlayer insulating film L3 in which the plugs P3 are buried. The conductive film CDLE is, for example, a titanium nitride (TiN) film which is formed by sputtering or the like. Then, a photoresist pattern RP1 is made over the conductive film CDLE by photolithography. Then, the lower electrode LE is formed as shown in FIG. 14 by patterning (etching) the conductive film CDLE using the photoresist pattern RP1 as an etching mask. The lower electrode LE is a patterned conductive film CDLE. After that, the photoresist pattern RP1 is removed. FIG. 14 shows the result of removal of the pattern.

Next, a capacitive insulating film YZ of the capacitor CP is formed. The capacitive insulating film YZ may be formed as follows.

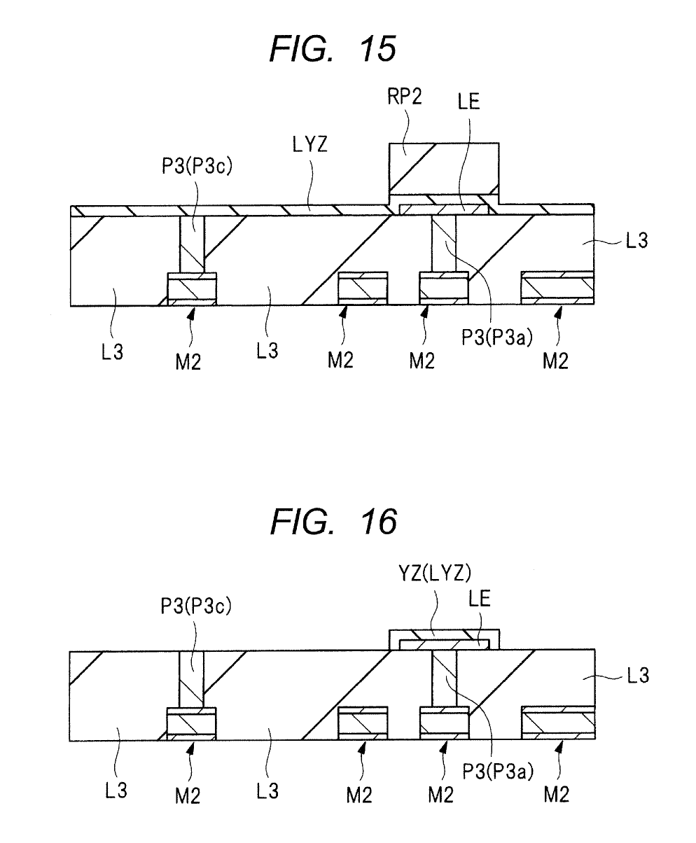

First, as shown in FIG. 15, an insulating film LYZ for the formation of the capacitive insulating film YZ is formed over the main surface (whole main surface) of the semiconductor substrate SB, namely the interlayer insulating film L3, so as to cover the lower electrode LE. The insulating film LYZ is, for example, a silicon nitride film which can be formed by the plasma CVD method or the like. Although a silicon nitride film is suitable as the insulating film LYX, instead it may be a silicon oxide film, tantalum oxide film or titanium oxide film. Then, a photoresist pattern RP2 is made over the insulating film LYZ by photolithography. Then, the capacitive insulating film YZ is formed as shown in FIG. 16 by patterning (etching) the insulating film LYZ using the photoresist pattern RP2 as an etching mask. The capacitive insulating film YZ is a patterned insulating film LYZ. After that, the photoresist pattern RP2 is removed. FIG. 16 shows the result of removal of the pattern.

In plan view, the lower electrode LE is contained in the capacitive insulating film YZ, which means that when the capacitive insulating film YZ is formed, the lower electrode LE is covered by the capacitive insulating film YZ and thus the lower electrode LE is not exposed.

Next, a wiring M3 in a third wiring layer and an upper electrode UE are formed over the interlayer insulating film L3. The wiring M3 and upper electrode UE may be formed as follows.

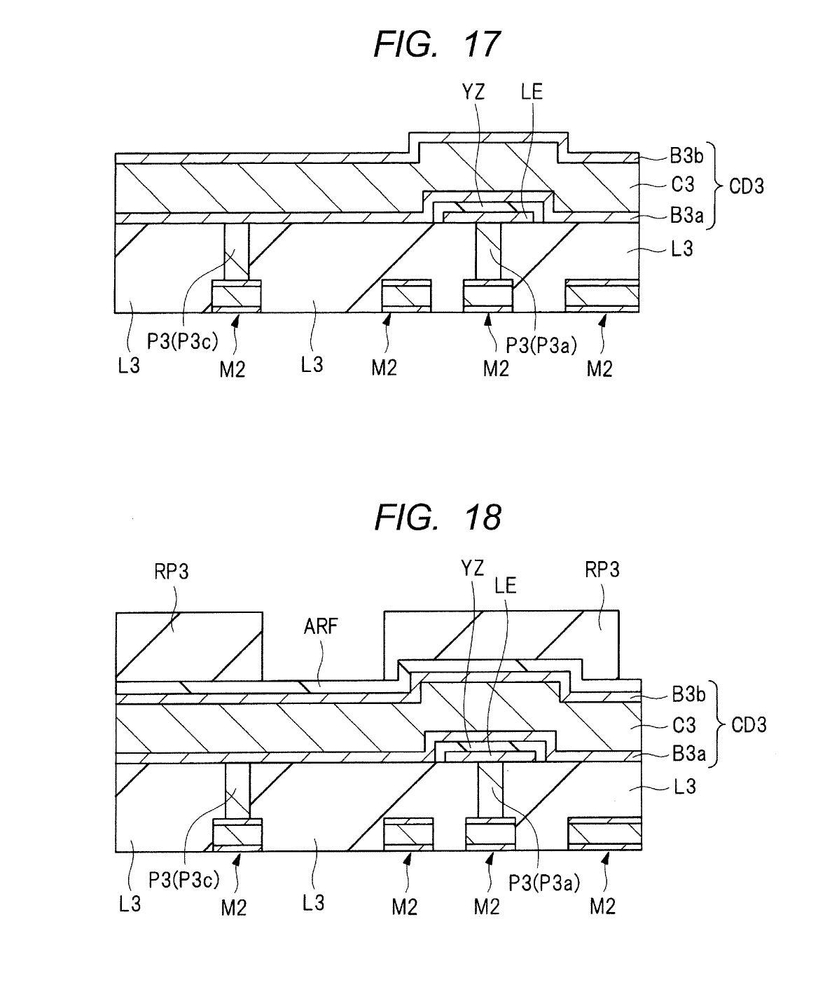

First, as shown in FIG. 17, a conductive film CD3 is formed over the main surface (whole main surface) of the semiconductor substrate SB, namely the interlayer insulating film L3, so as to cover the capacitive insulating film YZ. The conductive film CD3 serves as both a conductive film for the formation of the wiring M3 and a conductive film for the formation of the upper electrode UE. The conductive film CD3 is a laminated film including a barrier conductive film B3a, a main conductive film C3 over the barrier conductive film B3a, and a barrier conductive film B3b over the main conductive film C3 which can be formed by sputtering or the like. The materials of the films are as mentioned above. Then, as shown in FIG. 18, an insulating film ARF for antireflection is formed over the conductive film CD3. The insulating film ARF is, for example, a silicon oxynitride film which can be formed by CVD or the like. The insulating film ARF may be omitted unless required. Then, a photoresist pattern RP3 is made over the insulating film ARF (over the conductive film CD3 if the insulating film ARF is not formed) by photolithography. Then, the insulating film ARF and conductive film CD3 are etched sequentially using the photoresist pattern RP3 as an etching mask. Patterning is thus done on the laminated film including the conductive film CD3 and the insulating film ARF over the conductive film CD3. After that, the photoresist pattern RP3 is removed and then the insulating film ARF is selectively removed by etching (preferably by wet etching). Consequently, the wiring M3 and the upper electrode UE are formed from the patterned conductive film CD3 as shown in FIG. 19. Alternatively, the insulating film ARF may be unremoved and left over the wiring M3 and the upper electrode UE.

As explained so far, in this embodiment, the wiring M3 and upper electrode UE are formed by patterning the same conductive film CD3 for the wiring M3 and upper electrode UE by photolithography and etching. Thus, the wiring M3 and upper electrode UE are formed from the patterned conductive film CD3. The wiring M3 and upper electrode UE are formed in the same step.

Then, as shown in FIG. 20, an interlayer insulating film L4 is formed over the main surface (whole main surface) of the semiconductor substrate SB, namely the interlayer insulating film L3, so as to cover the wiring M3 and upper electrode UE. The interlayer insulating film L4 is, for example, a silicon oxide film. For example, the silicon oxide film may be a silicon oxide film made of TEOS which can be formed by the CVD method or it may be an HDP oxide film. After the formation of the interlayer insulating film L4, the planarity of the upper surface of the interlayer insulating film L4 may be increased by polishing it by the CMP method as necessary.

Then, as shown in FIG. 21, through holes S4 are made in the interlayer insulating film L4 by etching (preferably dry-etching) the interlayer insulating film L4 using a photoresist pattern (not shown) made over the interlayer insulating film L4 by photolithography as an etching mask. The through holes S4 penetrate the interlayer insulating film L4 and the upper surface of the wiring M3 or the upper electrode UE is exposed at the bottom of a through hole S4. Specifically, the upper surface of the upper electrode UE is exposed in the through hole S4 for burying the plug P4a to be coupled to the upper electrode UE and the upper surface of the wiring M3 is exposed in the through hole S4 for burying the plug P4c to be coupled to the wiring M3.

As shown in FIG. 22, the plugs P4 are formed in the through holes S4 by filling conductive film in the through holes S4. The plugs P4 are formed by the same method as the plugs P1.

Next, a wiring M4 in a fourth wiring layer is formed over the interlayer insulating film L4 in which the plugs P4 are buried. The wiring M4 may be formed as follows.

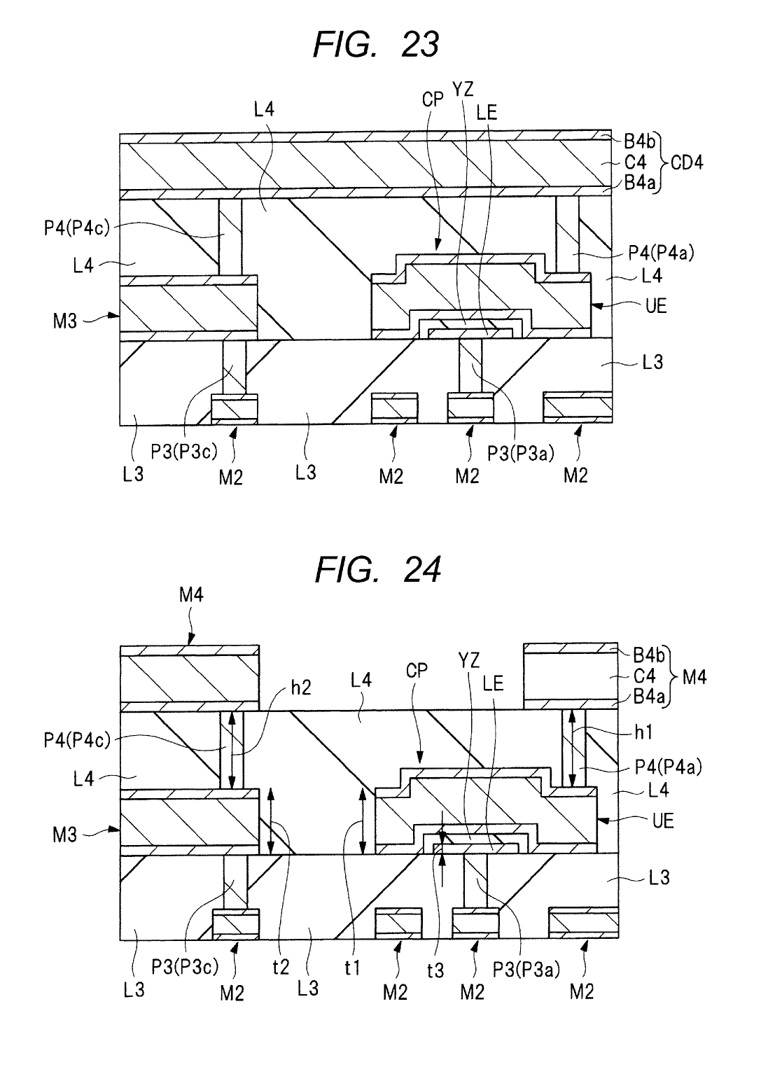

First, as shown in FIG. 23, a conductive film CD4 for the fourth wiring layer is formed over the interlayer insulating film L4 in which the plugs P4 are buried. The conductive film CD4 is a laminated film including a barrier conductive film B4a, a main conductive film C4 over the barrier conductive film B4a, and a barrier conductive film B4b over the main conductive film C4 which are formed by sputtering or the like. The materials of the films are as mentioned above. Then, the wiring M4 is formed from the patterned conductive film CD4 as shown in FIG. 24 by patterning the conductive film CD4 by photolithography and etching.

Then, as shown in FIG. 1, an interlayer insulating film L5 is formed over the main surface (whole main surface) of the semiconductor substrate SB, namely the interlayer insulating film L4, so as to cover the wiring M4. The interlayer insulating film L5 is, for example, a silicon oxide film. For example, the silicon oxide film may be a silicon oxide film made of TEOS which can be formed by the CVD method or it may be an HDP oxide film. After the formation of the interlayer insulating film L5, the planarity of the upper surface of the interlayer insulating film L5 may be increased by polishing it by the CMP method as necessary.

An explanation of the subsequent manufacturing steps is not given here. The number of wiring layers is not limited to four but a fifth wiring layer may be formed over the interlayer insulating film L5.

### Comparative Example

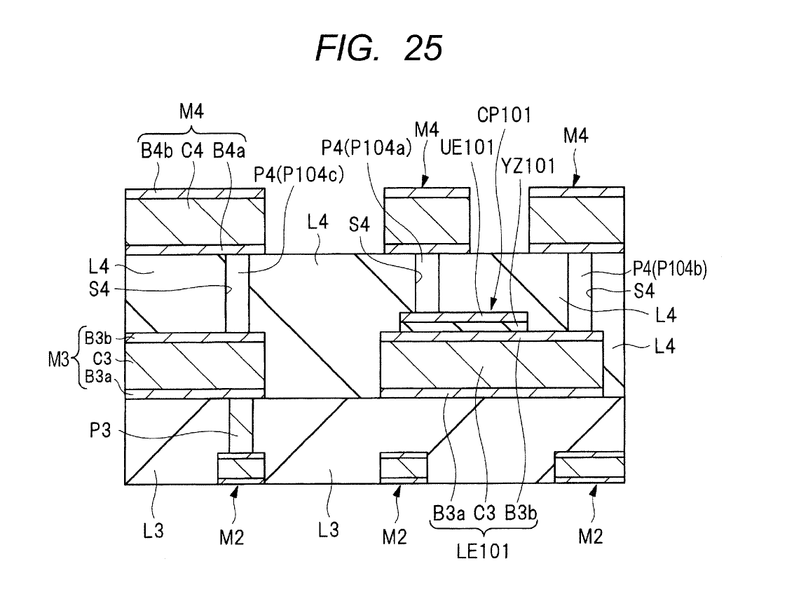

FIG. 25 is a sectional view of an essential part of the semiconductor device examined by the present inventors, showing its cross section corresponding to FIG. 24. In FIG. 25, for illustrative simplicity, the interlayer insulating film L2 and the layers under it are omitted and the interlayer insulating film L5 is also omitted.

The semiconductor device shown in FIG. 25 as the comparative example is also a semiconductor device having a MIM capacitor CP101, in which the capacitor CP101 is formed in a multilayer wiring structure made over a semiconductor substrate. Specifically, the capacitor CP101 includes a lower electrode LE101, an upper electrode UE 101, and a capacitive insulating film YZ101 interposed between the lower electrode LE101 and upper electrode UE101.

In the comparative example shown in FIG. 25, the lower electrode LE101 of the capacitor CP101 is formed from the conductive film pattern in the same layer as the wiring M3 in the third wiring layer. In other words, in the comparative example shown in FIG. 25, the lower electrode LE101 and the wiring M3 are formed by patterning the same conductive film (equivalent to the conductive film CD3). Therefore, in the comparative example shown in FIG. 25, the laminated constitution of the lower electrode LE101 is the same as the laminated constitution of the wiring M3 and the lower electrode LE101 and wiring M3 are both laminated films which include a barrier conductive film B3a, an aluminum-based main conductive film C3 over the barrier conductive film B3a, and a barrier conductive film B3b over the main conductive film C3. The upper electrode UE101 is formed over the lower electrode LE101 through the capacitive insulating film YZ101. The upper electrode UE101 is formed from a conductive film pattern different from that for the wiring M3, and for example, it is a titanium nitride (TiN) film. The capacitive insulating film YZ101 is, for example, a silicon nitride film.

According to the examination by the present inventors, the semiconductor device as the comparative example shown in FIG. 25 has the following problems.

In the comparative example shown in FIG. 25, after the formation of the conductive film (equivalent to the conductive film CD3) for the lower electrode LE101 and wiring M3, an insulating film is formed for the capacitive insulating film YZ101. When the insulating film for the capacitive insulating film YZ101 is formed, thermal stress might occur in the underlying conductive film (conductive film for the lower electrode LE101 and wiring M3), causing generation of hillocks (semispherical projections) on the surface of the wiring M3. Specifically, since the aluminum-based conductive film has a relatively low melting point, hillocks might be generated in the wiring M3 as an aluminum wiring due to the thermal stress which occurs during the formation of the insulating film for the capacitive insulating film YZ101. The generation of hillocks might result in deterioration in the reliability of the wiring M3. For example, hillocks might cause deterioration in the planarity of the wiring M3 (morphology deterioration) and generate leak current between wirings. In an effort to minimize hillocks during the formation of the insulating film for the capacitive insulating film YZ101, for example, if the temperature for the formation of the insulating film for the capacitive insulating film YZ101 is lowered, the range of choice of the material of the capacitive insulating film YZ101 would be narrow and the quality of the capacitive insulating film YZ101 might deteriorate. The deterioration in the quality of the capacitive insulating film YZ101 leads to deterioration in the reliability of the capacitor CP101.

Furthermore, in the comparative example shown in FIG. 25, while the capacitive insulating film YZ101 and the upper electrode UE101 lie over the lower electrode LE101, the insulating film for the capacitive insulating film YZ101 and the conductive film for the upper electrode UE101 do not lie over the wiring M3. Therefore, when etching is done on the conductive film for the upper electrode UE101 and the insulating film for the capacitive insulating film YZ101 for patterning, the upper surface of the wiring M3 is exposed and etched. This etching process might damage the wiring M3 and result in deterioration in the reliability of the wiring M3.

Furthermore, an interlayer insulating film L4 is formed so as to cover the wiring M3 and capacitor CP101 and plugs P4 are buried in through holes S4 made in the interlayer insulating film L4. In the comparative example shown in FIG. 25, among the plugs P4 are a plug P4 (P104c) located over the wiring M3 and coupled to the wiring M3, a plug P4 (P104a) located over the upper electrode UE101 and coupled to the upper electrode UE101, and a plug P4 (P104b) located over the lower electrode LE101's portion not covered by the upper electrode UE101 and coupled to the lower electrode LE101.

In the comparative example shown in FIG. 25, the plug P4 located over the lower electrode LE101's portion not covered by the upper electrode UE101 and coupled to the lower electrode LE101 is called plug P104b. In the comparative example shown in FIG. 25, the plug P4 located over the upper electrode UE101 formed over the lower electrode LE101 through the capacitive insulating film YZ101 and coupled to the upper electrode UE101 is hereinafter called P104a. Also, in the comparative example shown in FIG. 25, the plug P4 located over the wiring M3 and coupled to the wiring M3 is hereinafter called P104c.

Since the wiring M3 and the lower electrode LE101 are formed by patterning the same conductive film, they have almost the same thickness. Therefore, the plug P104c located over the wiring M3 has almost the same height as the plug P104b located over the lower electrode LE101's portion not covered by the upper electrode UE101. However, the height of the plug P104a located over the upper electrode UE101 is smaller than the height of the plug P104c located over the wiring M3 by the amount equivalent to the sum of the thicknesses of the capacitive insulating film YZ101 and upper electrode UE101. Therefore, the depth of the through hole S4 for burying the plug P104a is smaller than the depth of the through hole S4 for burying the plug P104c by the amount equivalent to the sum of the thicknesses of the capacitive insulating film YZ101 and upper electrode UE101. Therefore, in the etching step for making through holes S4 in the interlayer insulating film L4, when the through hole S4 (through hole S4 for burying the plug P104c) is made so as to reach the wiring M3, the upper electrode UE101 would be over-etched at the bottom of the through hole S4 (through hole S4 for burying the plug P104a) made over the upper electrode UE101. Over-etching of the upper electrode UE101 at the bottom of the through hole S4 might deteriorate the reliability of the capacitor CP101 having the upper electrode UE101, which might deteriorate the reliability of the semiconductor device having the capacitor CP101.

### <Main Features and Effects>

The semiconductor device according to this embodiment includes a semiconductor substrate SB, an interlayer insulating film L3 (first interlayer insulating film) formed over the semiconductor substrate SB, a wiring M3 (first wiring) and a lower electrode LE which are formed over the interlayer insulating film L3 and spaced from each other, an upper electrode UE formed over the interlayer insulating film L3 so as to cover the lower electrode LE, and a capacitive insulating film YZ interposed between the lower electrode LE and upper electrode UE. The lower electrode is a lower electrode for a capacitor CP, the upper electrode UE is an upper electrode for the capacitor CP, and the capacitive insulating film YZ is a capacitive insulating film for the capacitor CP. Furthermore, the semiconductor device according to this embodiment has, over the interlayer insulating film L3, the interlayer insulating film L4 (second interlayer insulating film) covering the wiring M3, lower electrode LE, capacitive insulating film YZ and upper electrode UE, and the plug P4c (third contact plug) buried in the interlayer insulating film L4 and located over the wiring M3 and electrically coupled to the wiring M3.

In this embodiment and the second embodiment (described later), the upper electrode UE is formed over the interlayer insulating film L3 so as to cover the whole lower electrode LE; on the other hand, in the third and fourth embodiments (described later), the upper electrode UE is formed over the interlayer insulating film L3 so as to cover the lower electrode LE partially. Thus, comprehensively, in the first to fourth embodiments, the upper electrode UE is formed over the interlayer insulating film L3 so as to cover the lower electrode LE at least partially.

One major feature of the semiconductor device according to this embodiment is that the wiring M3 and the upper electrode UE are formed from the conductive film pattern in the same layer. Hereinafter this is called the first feature. From another viewpoint, the first feature is that the upper electrode UE and the wiring M3 are formed by patterning the same conductive film (equivalent to the conductive film CD3).

Another major feature of the semiconductor device according to this embodiment is that it includes a plug P4a (second contact plug) buried in the interlayer insulating film L4 (second interlayer insulating film) and located over the upper electrode UE and electrically coupled to the upper electrode UE and the plug P4a lies over the upper electrode UE's portion not overlapping the lower electrode LE in plan view. Hereinafter this is called the second feature. From another viewpoint, the second feature is that the plug P4a lies over the area around the convex portion TB of the upper surface of the upper electrode UE which reflects the presence of the lower electrode LE and capacitive insulating film YZ (namely over the area lower than the convex portion TB).

A further major feature of the semiconductor device according to this embodiment is that it includes a plug P3a (first contact plug) which is buried in the interlayer insulating film L3, located under the lower electrode LE, and electrically coupled to the lower electrode LE. This is hereinafter called the third feature.

As the first feature of this embodiment, the wiring M3 and the upper electrode UE are formed from the conductive film pattern in the same layer. Since the wiring M3 and an electrode of the capacitor (the upper electrode UE in this example) are formed from the conductive film pattern in the same layer, the number of steps of manufacturing the capacitor CP is decreased, so the manufacturing cost of the semiconductor device is reduced. In addition, the semiconductor device manufacturing time can be shortened, leading to improvement in throughput.

In contrast, if the wiring M3 and the lower electrode LE101 of the capacitor are formed from the conductive film pattern in the same layer like the comparative example shown in FIG. 25, thermal stress might occur in the underlying conductive film (conductive film for both the lower electrode LE101 and wiring M3) and generate hillocks on the surface of the wiring M3 as mentioned above.

On the other hand, in this embodiment, the first feature is that not the lower electrode LE but the upper electrode UE is formed from the conductive film pattern in the same layer as the wiring M3. Therefore, the conductive film CD3 for the wiring M3 is formed after the formation of the insulating film LYZ for the capacitive insulating film YZ, which avoids the possibility that hillocks (semispherical projections) are generated on the surface of the wiring M3 due to the step of forming the insulating film LYZ for the capacitive insulating film YZ.

Especially, if the wiring M3 is an aluminum wiring whose main component is aluminum (Al), the possibility of generation of hillocks (semispherical projections) on the surface of the wiring M3 is high because the melting point of aluminum is relatively low. However, in this embodiment, even if the wiring M3 is an aluminum wiring, the possibility of generation of hillocks on the surface of the wiring M3 due to the step of forming the insulating film LYZ for the capacitive insulating film YZ is avoided because the conductive film CD3 for the wiring M3 is formed after the formation of the insulating film LYZ for the capacitive insulating film YZ.

In this embodiment, since the possibility that hillocks are generated on the surface of the wiring M3 is reduced or prevented, the reliability of the wiring M3 is enhanced and consequently the reliability of the semiconductor device is enhanced. If hillocks are generated in a wiring, deterioration in the planarity of the wiring (deterioration in morphology) might result, generating leak current between wirings. However, in this embodiment, this problem is prevented because the possibility of generation of hillocks in the wiring M3 is reduced or prevented.

Therefore, if the wiring (wiring M3 in this example) formed in the same layer as the upper electrode UE is aluminum-based, this embodiment offers a particularly advantageous effect.

In this embodiment, since the possibility of generation of hillocks on the surface of the wiring M3 due to the step of forming the insulating film LYZ for the capacitive insulating film YZ is avoided thanks to the first feature, the range of choice of the material of the capacitive insulating film YZ is widened. Thus, a suitable material for the capacitive insulating film of a capacitor can be selected for the capacitive insulating film YZ and it is easier to manufacture a semiconductor device having a capacitor. In addition, since the insulating film LYZ for the capacitive insulating film YZ can be formed at a suitable temperature for the selected material without worrying about the possibility of generation of hillocks, the quality of the capacitive insulating film YZ can be improved. Consequently, the reliability of the semiconductor device having the capacitor is enhanced.

The material of the capacitive insulating film YZ (material of the insulating film LYZ for the capacitive insulating film YZ) is desirably silicon nitride, though it depends on the required capacitance of the capacitor CP. Other desirable materials are silicon oxide (typically SiO₂), tantalum oxide (typically TaO), and titanium oxide (typically TiO₂) Therefore, desirably the capacitive insulating film is a silicon nitride film but it may be a silicon oxide film, tantalum oxide film or titanium oxide film.

When the temperature for the formation of the interlayer insulating film L4 is lowered, it is easier to reduce or prevent the possibility of generation of hillocks on the wiring M3 due to the step of forming the capacitive insulating film YZ. The thickness of the capacitive insulating film YZ is far smaller than the thickness of the interlayer insulating film L4 and it is important to improve the quality of the capacitive insulating film YZ in order to prevent leak current between the lower electrode LE and the upper electrode UE. In consideration of the quality of the capacitive insulating film YZ, it is desirable that the temperature for the formation of the insulating film LYZ for the capacitive insulating film YZ be suitable for the material selected for the insulating film LY. On the other hand, the required quality level of the interlayer insulating film L4 is lower than that of the capacitive insulating film YZ. Thus, the temperature for the formation of the interlayer insulating film L4 can be selected more freely than the temperature for the formation of the insulating film LYZ for the capacitive insulating film YZ.

For this reason, this embodiment is more effective when the temperature for the formation of the interlayer insulating film L4 is lower than the temperature for the formation of the insulating film LYZ for the capacitive insulating film YZ. In other words, this embodiment is more effective when the temperature for the formation of the insulating film LYZ for the capacitive insulating film YZ is higher than the temperature for the formation of the interlayer insulating film L4. This is because the possibility of generation of hillocks on the wiring M3 due to the step of forming the insulating film LYZ for the capacitive insulating film YZ is avoided even if the temperature for the formation of the insulating film LYZ for the capacitive insulating film YZ is high and if the temperature for the formation of the interlayer insulating film L4 is low, the possibility of generation of hillocks on the wiring M3 due to the step of forming the interlayer insulating film L4 is reduced or prevented.

In this embodiment, preferably the wiring M3 is an aluminum (Al)-based wiring and the lower electrode LE is made of a material whose melting point is higher than the melting point of aluminum (Al). This suppresses or prevents the generation of hillocks in the lower electrode LE due to the step of forming the insulating film YZ for the capacitive insulating film YZ. This is because the higher the melting point is, the less likely the generation of hillocks is and the use of a material with a lower melting point than the melting point of aluminum (Al) for the lower electrode LE suppresses or prevents the generation of hillocks in the lower electrode LE due to the step of forming the insulating film YZ for the capacitive insulating film YZ as compared with a case in which an aluminum wiring is used for the lower electrode (equivalent to the comparative example shown in FIG. 25). Consequently, the reliability of the capacitor CP is further enhanced and the reliability of the semiconductor device having the capacitor is further enhanced.

For the lower electrode LE, it is particularly desirable to use a titanium nitride (TiN) film, titanium (Ti) film, tantalum nitride (TaN) film, or tantalum (Ta) film. The melting point of titanium nitride (TiN) (2950° C.), melting point of titanium (Ti) (1668° C.), melting point of tantalum nitride (TaN) (3360° C.) and melting point of tantalum (Ta) (3020° C.) are much higher than the melting point of aluminum (Al) (660° C.). Among them, the melting points of titanium nitride (TiN), tantalum nitride (TaN), and tantalum (Ta) are very high and most suitable as the material of the lower electrode LE.

For all the lower barrier conductive films (B1a, B2a, B3a, B4a) and upper barrier conductive films (B1b, B2b, B3b, B4b) of the aluminum wirings (M1, M2, M3, M4), titanium nitride (TiN) films are particularly suitable. Therefore, it is particularly preferable that a titanium nitride (TiN) film be used for each of the barrier conductive film B3a and barrier conductive film B3b which constitute the wiring M3 and the upper electrode UE and a titanium nitride (TiN) film be used for the lower electrode LE. Consequently, the conductive film CDLE, barrier conductive film B3a and barrier conductive film B3b are made of the same material, thereby making the semiconductor device manufacturing process easier. Also, this is advantageous in reducing the semiconductor device manufacturing cost.

If the wiring M3 and the lower electrode LE101 of the capacitor are formed from the conductive film pattern in the same layer as in the comparative example shown in FIG. 25, the upper electrode UE101 and the capacitive insulating film YZ101 are formed by etching (patterning) the conductive film for the upper electrode UE101 and the insulating film for the capacitive insulating film YZ101 as mentioned above. In this etching process, the upper surface of the wiring M3 would be exposed and etched. In that case, etching might damage the wiring M3 and cause deterioration in the reliability of the wiring M3.

In contrast, in this embodiment, the first feature is that not the lower electrode LE but the upper electrode UE is formed from the conductive film pattern in the same layer as the wiring M3. Therefore, the wiring M3 is formed after the formation of the lower electrode LE and the capacitive insulating film YZ, so the wiring M3 is not etched in the step of etching for the lower electrode LE and in the step of etching for the capacitive insulating film YZ. This suppresses or prevents damage to the wiring M3 by etching, leading to higher reliability of the wiring M3. Therefore, the reliability of the semiconductor device is enhanced.

In the comparative example shown in FIG. 25, the height of the plug P104a coupled to the upper electrode UE101 is smaller than the height of the plug P104c coupled to the wiring M3 by the amount equivalent to the sum of the thicknesses of the capacitive insulating film YZ101 and upper electrode UE101. For this reason, the depth of the through hole S4 for burying the plug P104a is smaller than the depth of the through hole S4 for burying the plug P104c by the amount equivalent to the sum of the thicknesses of the capacitive insulating film YZ101 and upper electrode UE101. Therefore, in the step of etching to form through holes S4, when a through hole S4 (through hole S4 for burying the plug P104c) is made so as to reach the wiring M3, the upper electrode UE101 would be over-etched at the bottom of the through hole S4 (through hole S4 for burying the plug P104a) made over the upper electrode UE101. Over-etching of the upper electrode UE101 at the bottom of the through hole S4 might deteriorate the reliability of the capacitor CP101 having the upper electrode UE101.

On the other hand, as the second feature of this embodiment, the plug P4a buried in the interlayer insulating film L4 lies over the upper electrode UE's portion not overlapping the lower electrode LE in plan view and the plug P4a is electrically coupled to the upper electrode UE. Consequently, the upper electrode UE can be electrically coupled to the wiring M4 through the plug P4a overlying the upper electrode UE. As the third feature of this embodiment, the plug P3a buried in the interlayer insulating film L3 lies under the lower electrode LE and the plug P3a is electrically coupled to the lower electrode LE. Consequently, the lower electrode LE can be electrically coupled to the wiring M2 through the plug P3a underlying the lower electrode LE.

It is assumed that a case different from this embodiment, in which the plug P4 buried in the interlayer insulating film L4 lies over the upper electrode UE's portion overlapping the lower electrode LE in plan view and the plug P4 is electrically coupled to the upper electrode UE. In that case, the height of the plug P4 overlying the upper electrode UE's portion overlapping the lower electrode LE in plan view is smaller than the height of the plug P4c overlying the wiring M3 by the amount equivalent to the sum of the thicknesses of the capacitive insulating film YZ and lower electrode LE. In that case, in the step of etching to form through holes S4 in the interlayer insulating film L4, when a through hole S4 (through hole S4 for burying the plug P4c) is made so as to reach the wiring M3, the upper electrode UE101 would be over-etched at the bottom of the through hole S4 made over the upper electrode UE.

In contrast, as the first feature of this embodiment, since the upper electrode UE and wiring M3 are formed from the conductive film pattern in the same layer, the thickness t1 of the upper electrode UE is almost equal to the thickness t2 of the wiring M3 (t1=t2). Thicknesses t1 and t2 are shown in FIG. 24. As the second feature, the plug P4a lies over the upper electrode UE's portion not overlapping the lower electrode LE in plan view and the plug P4a is electrically coupled to the upper electrode UE. From another viewpoint, the plug P4a lies over the area around the convex portion TB of the upper surface of the upper electrode UE which reflects the presence of the lower electrode LE and the capacitive insulating film YZ (namely over the area lower than the convex portion TB). Therefore, the height h1 of the plug P4a overlying the upper electrode UE is virtually equal to the height h2 of the plug P4c overlying the wiring M3 (h1=h2). Heights h1 and h2 are shown in FIG. 24. Therefore, the depth d1 of the through hole S4 in which the plug P4a is buried is virtually equal to the depth d2 of the through hole S4 in which the plug P4c is buried (d1=d2). Depths d1 and d2 are shown in FIG. 21.

Therefore, in this embodiment, in the etching step for making through holes S4 in the interlayer insulating film L4, when a through hole S4 (through hole S4 for burying the plug P4c) is made so as to reach the wiring M3, over-etching of the upper electrode UE101 at the bottom of the through hole S4 (through hole S4 for burying the plug P4a) made over the upper electrode UE is suppressed or prevented. Also, in the etching step for making through holes S4 in the interlayer insulating film L4, when a through hole S4 (through hole S4 for burying the plug P4a) is made so as to reach the upper electrode UE, over-etching of the wiring M3 at the bottom of the through hole S4 (through hole S4 for burying the plug P4c) made over the wiring M3 is suppressed or prevented. Consequently, since over-etching of the wiring M3 and upper electrode UE in the step of making through holes S4 in the interlayer insulating film L4 is suppressed or prevented, the reliability of the capacitor CP and wiring M3 is enhanced. Thus, the reliability of the semiconductor device is enhanced.

As mentioned above, in this embodiment, in order to make the height h1 of the plug P4a coupled to the upper electrode UE equal to the height h2 of the plug P4c coupled to the wiring M3, the plug P4a coupled to the upper electrode UE is located not over the upper electrode UE's portion overlapping the lower electrode LE in plan view but over the upper electrode UE's portion not overlapping the lower electrode LE in plan view. From another viewpoint, the plug P4a lies over the area around the convex portion TB of the upper surface of the upper electrode UE which reflects the presence of the lower electrode LE and the capacitive insulating film YZ (namely over the area lower than the convex portion TB). More specifically, in plan view, the plug P4a lies over the upper electrode UE's portion overlapping neither the lower electrode LE nor the capacitive insulating film YZ and overlying the interlayer insulating film L3, the upper surface of which is almost equal in height to the upper surface of the wiring M3. Therefore, although the plug P4a overlaps the upper electrode UE in plan view, it overlaps neither the lower electrode LE nor the capacitive insulating film YZ and the upper surface of the upper electrode UE's portion over which the plug P4a lies is almost equal in height to the upper surface of the wiring M3 over which the plug P4c lies. As a consequence, the height h1 of the plug P4a is almost equal to the height h2 of the plug P4c (h1=h2).

In this embodiment, the plug P4a is located over the upper electrode UE's portion whose upper surface is almost equal in height to the upper surface of the wiring M3 because it does not overlap the lower electrode LE (more specifically it overlaps neither the lower electrode LE nor the capacitive insulating film YZ). This suppresses or prevents over-etching of the wiring M3 and upper electrode UE in the etching step for making through holes S4 in the interlayer insulating film L4. Consequently, the reliability of the capacitor CP and wiring M3 is enhanced and the reliability of the semiconductor device is thus enhanced.

In this embodiment, preferably the plug P4 buried in the through hole (S4) of the interlayer insulating film L4 (the plug P4 coupled to the upper electrode UE) is not formed over the upper electrode UE's portion overlapping the lower electrode LE (or the capacitive insulating film YZ) in plan view. From another viewpoint, preferably no plug P4 is formed over the convex portion TB of the upper surface of the upper electrode UE which reflects the presence of the lower electrode LE and the capacitive insulating film YZ. This is very effective in suppressing or preventing over-etching of the upper electrode UE in the etching step for making through holes S4 in the interlayer insulating film L4.

It is assumed that a case different from this embodiment, in which there is an area over the lower electrode LE in which the upper electrode UE and capacitive insulating film YZ do not lie and a plug P4 lies over the lower electrode LE in the area in which the upper electrode UE and capacitive insulating film YZ do not lie, and the plug P4 is electrically coupled to the lower electrode LE. In this case, because of the difference in thickness between the lower electrode LE and the wiring M3, the height of the plug P4 overlying the lower electrode L4 would be different from the height of the plug P4 overlying the wiring M3. Also, in this case, because the depth between the through hole S4 made over the lower electrode LE is different from the depth of the through hole S4 made over the wiring M3, the wiring M3 or the lower electrode LE would be over-etched at the bottom of the through hole S4.

In contrast, as the third feature of this embodiment, the plug P3a buried in the interlayer insulating film L3 lies under the lower electrode LE and the plug P3a is electrically coupled to the lower electrode LE. Since the plug (P3a) coupled to the lower electrode LE is formed under the lower electrode LE, it is unnecessary to form a plug (P4) to be coupled to the lower electrode LE, over the lower electrode LE. Therefore, in the etching step for making through holes S4 in the interlayer insulating film L4, it is unnecessary to make a through hole S4 to reach the lower electrode LE, which avoids over-etching of the wiring M3 or the lower electrode LE at the bottom of the through hole S4 which might be caused by making a through hole S4 to reach the lower electrode LE. Consequently the reliability of the capacitor CP and wiring M3 is enhanced. Thus, the reliability of the semiconductor device is enhanced.

As mentioned above, in this embodiment, the wiring M3 and the upper electrode UE of the capacitor CP are formed from the conductive film pattern in the same layer, and the contact plug (plug P4a in this example) coupled to the upper electrode UE of the capacitor and the contact plug (plug P3a in this example) coupled to the lower electrode LE of the capacitor CP are carefully arranged. Consequently, the reliability of the semiconductor device having the capacitor and wirings is enhanced.

Furthermore, in order to reduce wiring resistance, preferably the wiring M3 has a certain degree of thickness. On the other hand, if the lower electrode LE is too thick, the whole lamination including the lower electrode LE, capacitive insulating film YZ, and upper electrode UE would be too thick, making it necessary to increase the thickness of the interlayer insulating film L4. Also, for the wiring M3, resistance is less important than for the lower electrode LE. For these reasons, it is preferable that the thickness t3 of the lower electrode LE be smaller than the thickness t2 of the wiring M3 (t3<t2). Since the thickness t1 of the upper electrode UE is almost equal to the thickness t2 of the wiring M3, it is preferable that the thickness t3 of the lower electrode LE be smaller than the thickness t1 of the upper electrode UE (t3<t1). Thicknesses t1, t2, and t3 are shown in FIG. 24.

When the thickness t3 of the lower electrode LE is smaller than the thickness t2 of the wiring M3, if a plug P4 coupled to the lower electrode LE is formed over the lower electrode LE unlike this embodiment, at the time of making a through hole S4 to reach the lower electrode LE the wiring M3 would be over-etched at the bottom of the through hole S4 made over the wiring M3. In contrast, in this embodiment, since the plug P3a coupled to the lower electrode LE is formed under the lower electrode LE instead of forming a plug P4 coupled to the lower electrode LE over the lower electrode LE, it is unnecessary to make a through hole S4 to reach the lower electrode LE. For this reason, even when the thickness t3 of the lower electrode LE is smaller than the thickness t2 of the wiring M3, over-etching of the wiring M3 which would occur if a through hole S4 is made to reach the lower electrode LE is avoided.

In the explanations of the first embodiment and the second to fifth embodiments which will be described below, it is assumed that the upper electrode UE of the capacitor CP is formed in the same layer as the wiring M3 in the third wiring layer (namely the capacitor CP is formed in the third wiring layer). However, the wiring layer in which the capacitor is formed is not limited to the third wiring layer. Instead, for example, the capacitor CP may be formed in the second wiring layer and in that case, the upper electrode UE of the capacitor C will be formed in the same layer as the wiring M2.

In the first embodiment and the second to fifth embodiments, the number of wiring layers in the multilayer wiring structure formed over the semiconductor substrate SB is not limited to four but it may be any other number and the capacitor CP may be formed in any wiring layer in the multilayer wiring structure.

Furthermore, in the first embodiment and the second to fifth embodiments, some portion of the upper electrode UE may be used as a wiring. Specifically, a portion of the upper electrode UE which does not overlap the lower electrode LE in plan view and extends over the interlayer insulating film L3 may be used as a wiring. In other words, a portion of the upper electrode UE which does not overlap the lower electrode LE in plan view and overlies the interlayer insulating film L3 may be made to extend over the interlayer insulating film L3 like a wire so that the portion of the upper electrode UE overlying the interlayer insulating film L3 functions as a wiring.

### Second Embodiment

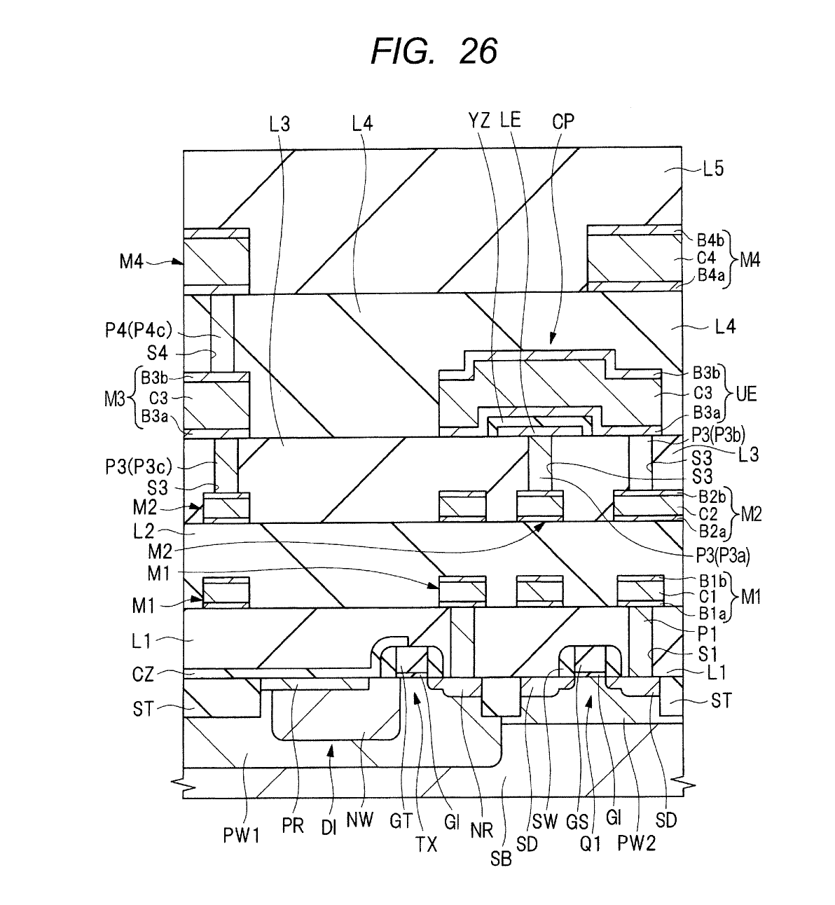

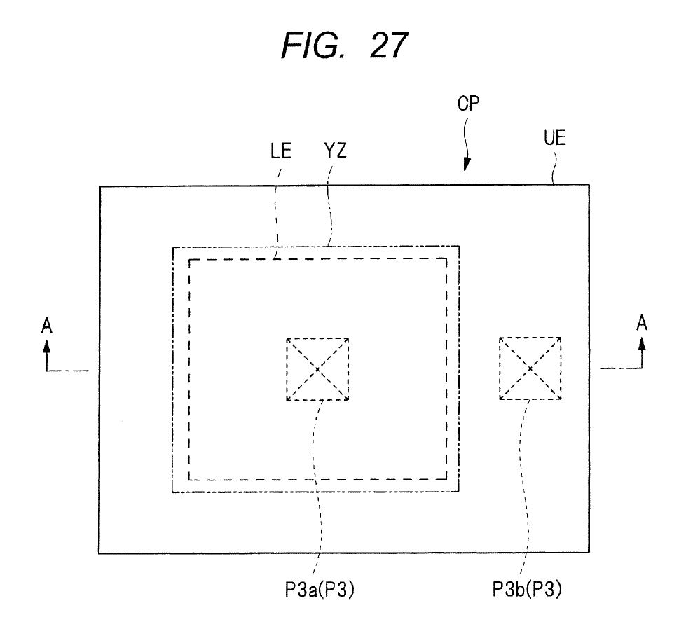

FIG. 26 is a sectional view of an essential part of the semiconductor device according to the second embodiment which corresponds to FIG. 1 for the first embodiment. FIG. 27 is a plan view of the essential part of the semiconductor device according to the second embodiment which corresponds to FIG. 2 for the first embodiment.

In the first embodiment, the contact plug coupled to the upper electrode UE is the plug P4a buried in the through hole S4 of the interlayer insulating film L4 and the plug P4a lies over the upper electrode UE's portion not overlapping the lower electrode LE in plan view.

On the other hand, in the second embodiment, the contact plug coupled to the upper electrode UE is not a plug P4 buried in a through hole S4 of the interlayer insulating film L4 but a plug P3 (P3b) buried in a through hole S3 of the interlayer insulating film L3 and the plug P3 (P3b) lies under the upper electrode UE's portion not overlapping the lower electrode LE in plan view. Basically the other elements are the same as in the first embodiment and their descriptions are omitted here. Only the difference from the first embodiment will be described below.

In the second embodiment, as can be understood from FIGS. 26 and 27, the plug P3 (P3b) buried in the interlayer insulating film L3 is located under the upper electrode UE and electrically coupled to the upper electrode UE. Among the plugs P3, the plug P3 located under the upper electrode UE and electrically coupled to the upper electrode UE is designated by sign P3b and hereinafter called plug P3b. The upper surface of the plug P3b abuts on the lower surface of the upper electrode UE so that the plug P3b and the upper electrode UE are electrically coupled.

In short, in the second embodiment, the plug P4a in the first embodiment is replaced by the plug P3b.

The plug P3b, located under the upper electrode UE, functions to couple the upper electrode UE and the wiring M2 located under the plug P3b electrically. In other words, the plug P3b is located between the upper electrode UE and wiring M2 and the upper surface of the plug P3b abuts on the lower surface of the upper electrode UE so that the plug P3b and the wiring M2 are electrically coupled, and the lower surface of the plug P3b abuts on the upper surface of the wiring M2 so that the plug P3b and the wiring M2 are electrically coupled. Thus, the plug P3b electrically couples the upper electrode UE overlying the plug P3b and the wiring M2 underlying the plug P3b.

The second embodiment is the same as the first embodiment in that the plug P3a lies under the lower electrode LE and the plug P3a and the lower electrode LE are electrically coupled. The plug P3a located under the lower electrode LE functions to couple the lower electrode LE and the wiring M2 underlying the plug P3a electrically.

The plug P3b lies under the upper electrode UE's portion not overlapping the lower electrode LE in plan view. More specifically, it lies under the upper electrode UE's portion overlapping neither the lower electrode LE nor the capacitive insulating film YZ in plan view. Therefore, while there is space for the formation of the lower electrode LE, the plug P3b can be coupled to the upper electrode UE without being hampered by the lower electrode LE.

In other words, the plug P3b located under the upper electrode UE and electrically coupled to the upper electrode UE does not overlap the lower electrode LE in plan view. More specifically, in plan view the plug P3b is located so as to overlap the upper electrode UE but not to overlap the lower electrode LE. In other words, in plan view, some portion of the upper electrode UE overlaps the lower electrode LE and the other portion does not overlap it and the plug P3b lies under the portion of the upper electrode UE which does not overlap the lower electrode LE. Thus, in plan view, the plug P3b overlaps the upper electrode UE but does not overlap the lower electrode LE. Therefore, the plug P3b abuts on the upper electrode UE and is electrically coupled to the upper electrode UE but it does not abut on the lower electrode LE.

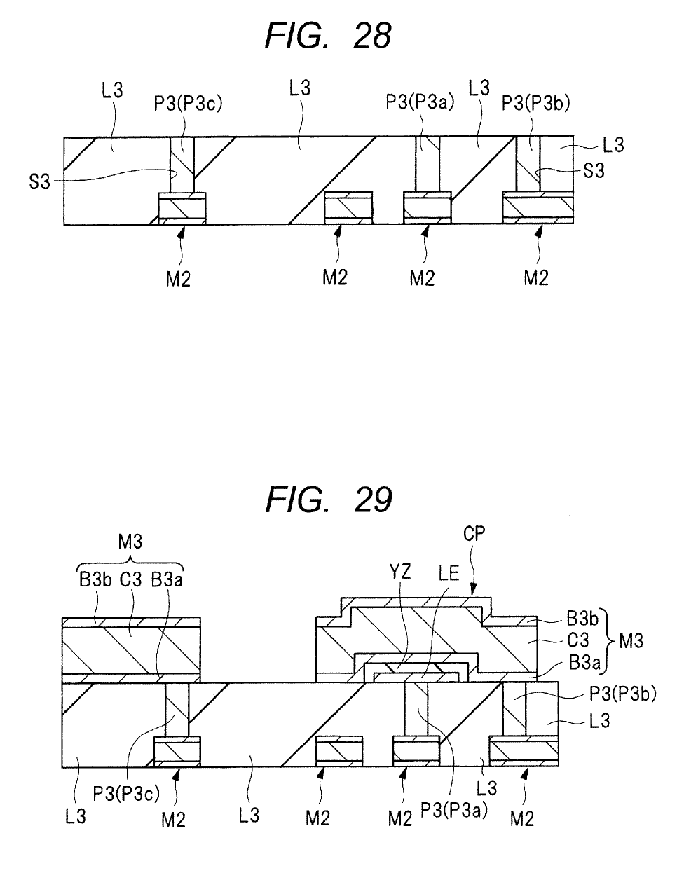

Next, regarding the semiconductor device manufacturing process according to the second embodiment, the different points from the first embodiment will be described. FIGS. 28 and 29 are sectional views of the essential part of the semiconductor device in manufacturing steps according to the second embodiment, in which FIGS. 28 and 29 correspond to FIG. 12 and FIG. 19 for the first embodiment, respectively.

As shown in FIG. 28, in the second embodiment, when through holes S3 are made in the interlayer insulating film L3, a through hole S3 for burying the plug P3b is also made, and when plugs P3 are formed inside the through holes S3, the plug P3b is also formed. Then, by carrying out the same steps as in the first embodiments (the steps shown in FIGS. 13 to 19), the wiring M3 and the capacitor CP are formed as shown in FIG. 29. Here the plug P3b lies under the upper electrode UE's portion not overlapping the lower electrode LE so that the plug P3b and the upper electrode UE are electrically coupled.

The other steps of the semiconductor device manufacturing process are the same as in the first embodiment and their descriptions are omitted here.

The second embodiment is different from the first embodiment in the second feature among the first to third features of the first embodiment. The second feature of the second embodiment is that a plug P3b (second contact plug) buried in the interlayer insulating film L3 (first interlayer insulating film) and located under the upper electrode UE and electrically coupled to the upper electrode UE is provided and the plug 3Pb is located under the upper electrode UE's portion not overlapping the lower electrode LE in plan view. The second embodiment is the same as the first embodiment in that there is no plug P4 (plug P4 coupled to the upper electrode UE) over the upper electrode UE's portion overlapping the lower electrode LE.

The second embodiment also brings about almost the same advantageous effects as the first embodiment.

Whereas in the first embodiment the plug P4a coupled to the upper electrode UE is located over the upper electrode UE's portion not overlapping the lower electrode LE in plan view, in the second embodiment the plug P3b coupled to the upper electrode UE is located under the upper electrode UE's portion not overlapping the lower electrode LE in plan view.

Accordingly, in the first embodiment, the height of the plug P4a coupled to the upper electrode UE is almost equal to the height of the plug P4c coupled to the wiring M3, thereby preventing over-etching of the upper electrode UE in the etching step for making through holes S4 in the interlayer insulating film L4. On the other hand, in the second embodiment, the plug P3b coupled to the upper electrode UE is located under the upper electrode UE, thereby preventing over-etching of the upper electrode UE in the etching step for making through holes S4 in the interlayer insulating film L4. Consequently, the reliability of the capacitor CP and wiring M3 is enhanced and the reliability of the semiconductor device is thus enhanced.

In the first embodiment, the plug P4a coupled to the upper electrode UE and the plug P3a coupled to the lower electrode LE are formed in different layers and the parasitic capacitance between the plug P4a and the plug P3a is very small and almost ignorable. Also, the wiring M4 coupled to the upper electrode UE through the plug P4a and the wiring M2 coupled to the lower electrode LE through the plug P3a are formed in different wiring layers and the parasitic capacitance between these wirings is very small and almost ignorable. Therefore, the capacitance value of the capacitor CP can be determined depending on the lower electrode LE, upper electrode UE, and capacitive insulating film YZ, so the capacitance value of the capacitor CP can be almost as designed.

On the other hand, in the second embodiment, since the plug P3b coupled to the upper electrode UE and the plug P3a coupled to the lower electrode LE are formed in the same layer, a parasitic capacitance between the plug P3b and the plug P3a may be generated. Also, the wiring M2 coupled to the upper electrode UE through the plug P3b and the wiring M2 coupled to the lower electrode LE through the plug P3a are formed in the same wiring layer, so a parasitic capacitance between these wirings may be generated.

Therefore, the first embodiment is more advantageous than the second embodiment in suppressing the parasitic capacitance and controlling the actual capacitance value of the capacitor CP to the design value. Thus, the first embodiment is excellent in terms of the ease of designing a capacitor.

However, in designing the wiring layout of the entire multilayer wiring structure, there are cases that coupling the upper electrode UE to the wiring M2 under the upper electrode UE through the plug P3b is more advantageous than coupling the upper electrode UE to the wiring M4 over the upper electrode UE through the plug P3b. In that case, the second embodiment is useful because the lower electrode LE and the upper electrode UE are coupled to the wirings in the same wiring layer through the plugs 3a and P3b.

### Third Embodiment

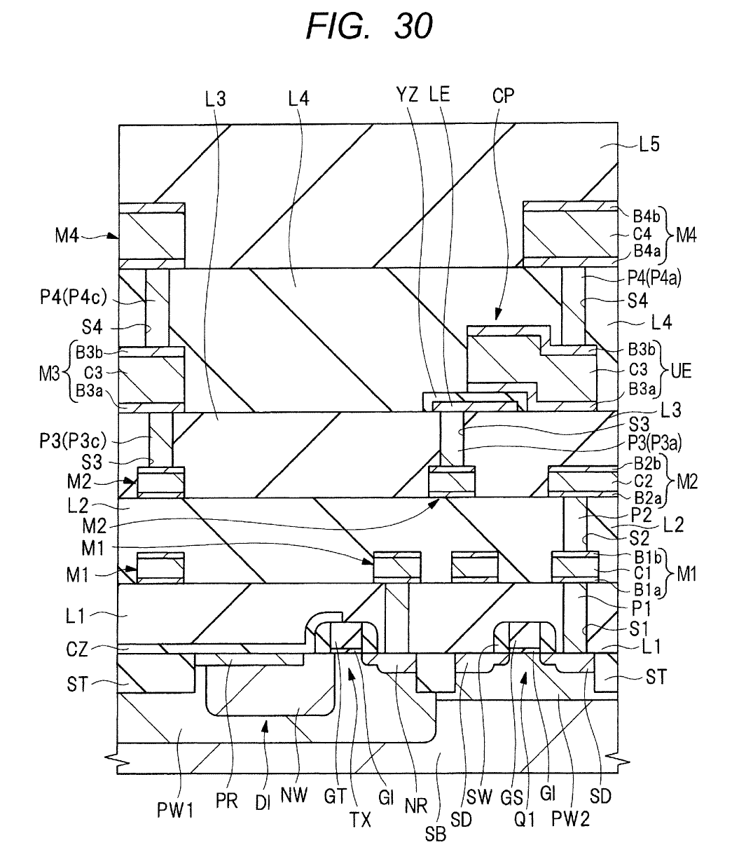

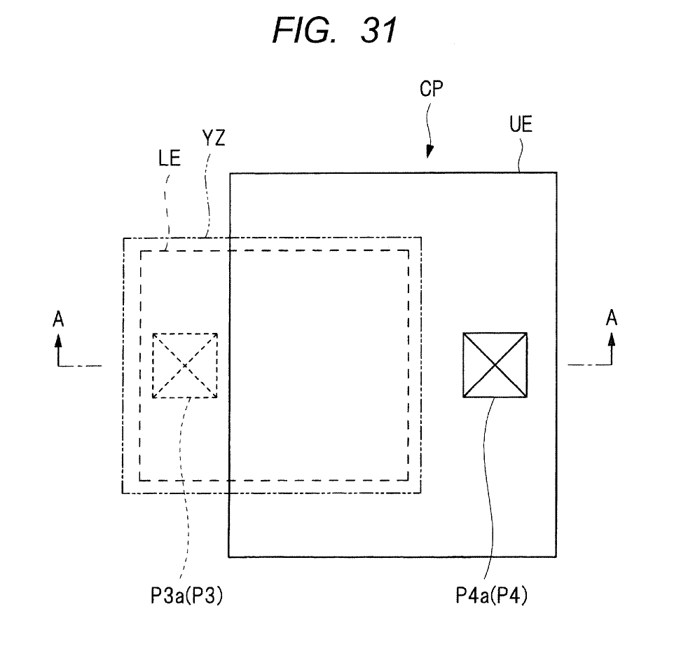

FIG. 30 is a sectional view of an essential part of the semiconductor device according to the third embodiment which corresponds to FIG. 1 for the first embodiment. FIG. 31 is a plan view of the essential part of the semiconductor device according to the third embodiment which corresponds to FIG. 2 for the first embodiment.

In the first embodiment, in plan view, the lower electrode LE entirely overlaps the upper electrode UE and does not have any portion not overlapping the upper electrode UE. In other words, in the first embodiment, in plan view the lower electrode LE is contained in the capacitive insulating film YZ and the capacitive insulating film YZ is contained in the upper electrode UE.

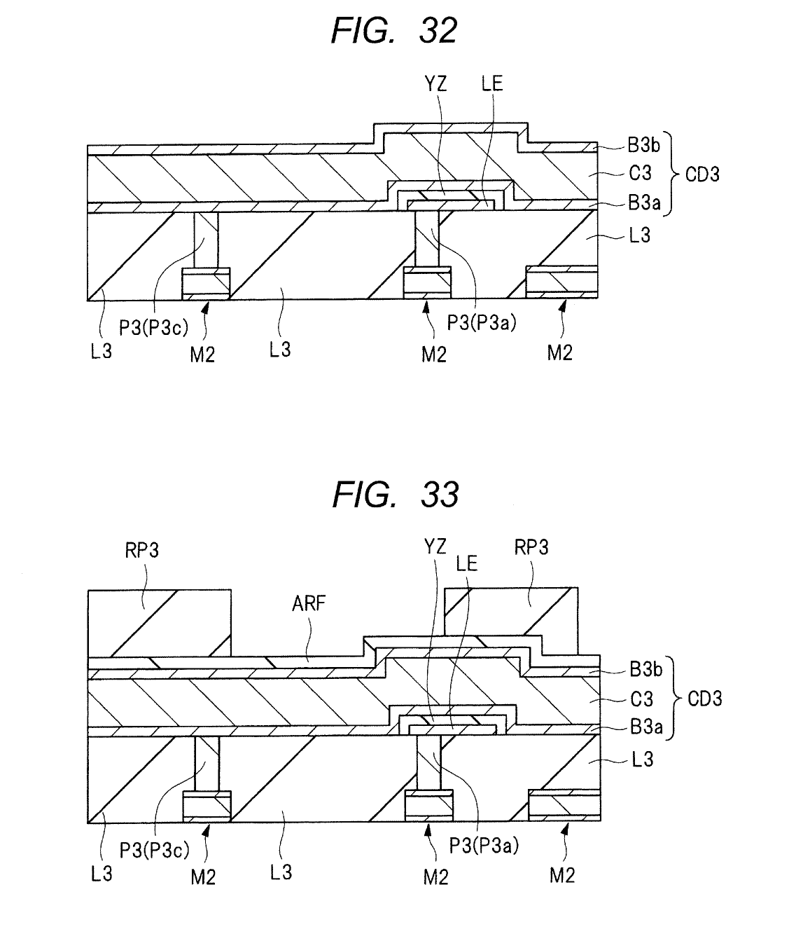

In contrast, in the third embodiment, as shown in FIGS. 31 and 32, in plan view, some portion of the lower electrode LE overlaps the upper electrode UE and the other portion does not overlap it. In other words, in plan view, while the lower electrode LE is contained in the capacitive insulating film YZ, the upper electrode UE overlaps the lower electrode LE not entirely but partially. Specifically, while the entire lower electrode LE is covered by the capacitive insulating film YZ, the upper electrode UE does not cover the capacitive insulating film YZ entirely and the lower electrode LE has a portion facing the upper electrode UE through the capacitive insulating film YZ and a portion not facing the upper electrode UE through the capacitive insulating film YZ.

Basically, the other elements of the third embodiment are the same as in the first embodiment.

The third embodiment is the same as the first embodiment in that the plug P3a is located under the lower electrode LE and the plug P3a and the lower electrode LE are electrically coupled. The plug P3a located under the lower electrode LE functions to couple the lower electrode LE and the wiring M2 located under the plug P3a electrically.

Furthermore, the third embodiment is the same as the first embodiment in that the plug P4a lies over the upper electrode UE's portion not overlapping the lower electrode LE in plan view and the plug P4a and the upper electrode UE are electrically coupled. In other words, the third embodiment is the same as the first embodiment in that the plug P4a is located in the area of the upper surface of the upper electrode UE around the convex portion TB (namely the area lower than the convex portion TB). The plug P4a functions to electrically couple the upper electrode UE and the wiring M4 located over the plug P4a.

Furthermore, the third embodiment is the same as the first embodiment in that there is no plug P4 (plug P4 coupled to the upper electrode UE) over the upper electrode UE's portion overlapping the lower electrode LE in plan view. In other words, the third embodiment is the same as the first embodiment in that there is no plug P4 (plug P4 coupled to the upper electrode UE) over the convex portion TB of the upper surface of the upper electrode UE.

Furthermore, the third embodiment is the same as the first embodiment in that there is no plug P4 (plug P4 coupled to the lower electrode LE) over the lower electrode LE. Therefore, in the third embodiment, a plug P4 (contact plug) which is buried in the interlayer insulating film L4 and coupled to the lower electrode LE is not formed over the lower electrode LE's portion not overlapping the upper electrode UE in plan view.

Next, regarding the semiconductor device manufacturing process according to the third embodiment, the different points from the first embodiment will be described. FIGS. 32 to 35 are sectional views of the essential part of the semiconductor device in manufacturing steps according to the third embodiment, in which FIGS. 32, 33, 34, and 35 correspond to FIGS. 17, 18, 19, and 22 for the first embodiment, respectively.

In the third embodiment, the structure shown in FIG. 32 (which corresponds to FIG. 17) is obtained as in the first embodiment. In the third embodiment, the steps until and including the formation of the conductive film CD3 are the same as in the first embodiment.

After that, an antireflection insulating film ARF is formed over the conductive film CD3 as shown in FIG. 33, then a photoresist pattern RP3 is made over the insulating film ARF by photolithography. The insulating film ARF is omissible. While in the first embodiment the lower electrode LE is contained in the photoresist pattern RP3 in plan view, in the third embodiment the lower electrode LE has a portion overlapping the photoresist pattern RP3 and a portion not overlapping it in plan view.

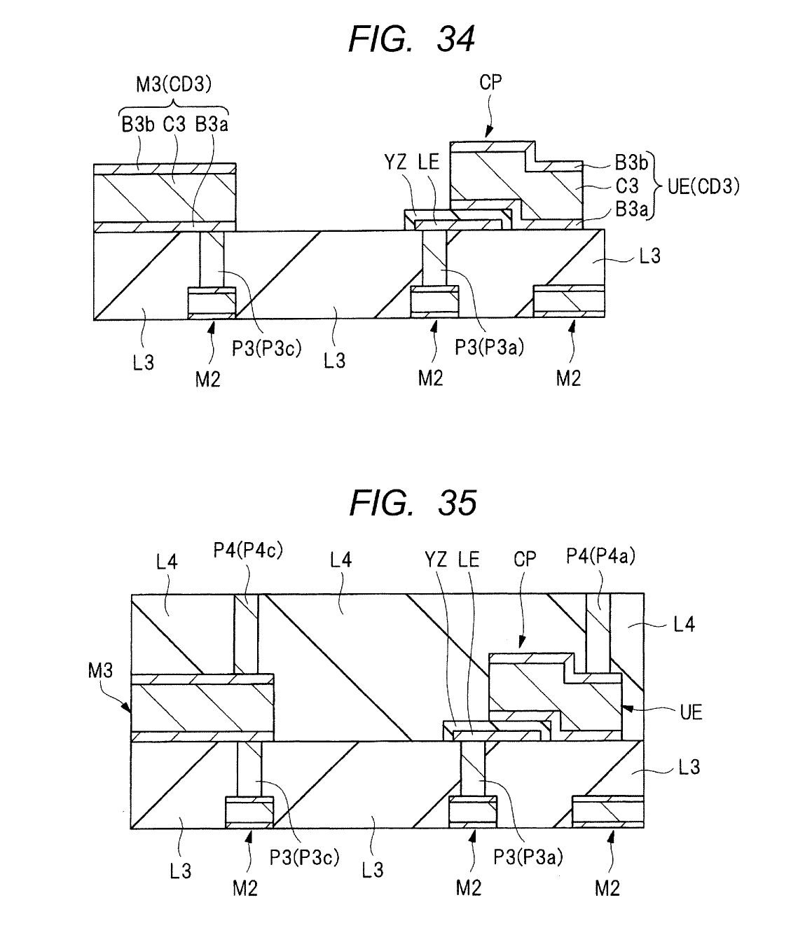

Then, the insulating film ARF and conductive film CD3 are etched sequentially using the photoresist pattern RP3 as an etching mask as in the first embodiment. Then, the photoresist pattern RP3 is removed and the insulating film ARF is selectively removed by etching. Instead, the insulating film ARF may be unremoved and left over the wiring M3 and the upper electrode UE. Consequently, the wiring M3 and the upper electrode UE are completed as the patterned conductive film CD3 as shown in FIG. 34.

Here, in the first embodiment, since the lower electrode LE is contained in the photoresist pattern RP3 in plan view, when the upper electrode UE is formed, the lower electrode LE is contained in the upper electrode UE in plan view. In contrast, in the third embodiment, since the lower electrode LE has a portion not overlapping the photoresist pattern RP3 and a portion not overlapping it in plan view, when the upper electrode UE is formed, the lower electrode LE has a portion overlapping the upper electrode UE and a portion not overlapping it in plan view.

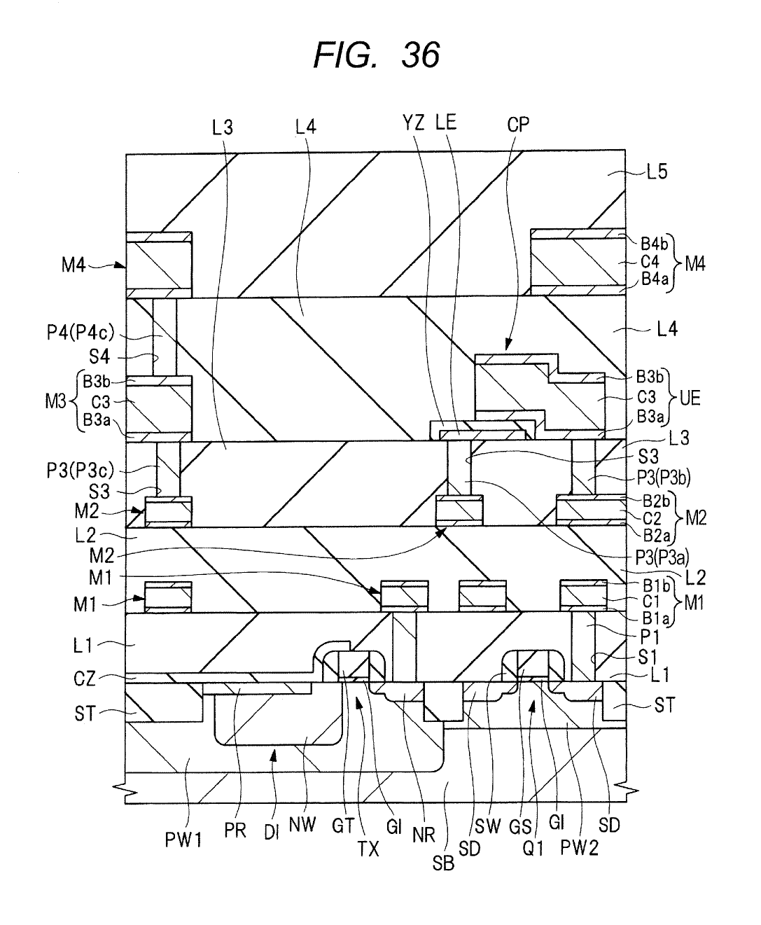

The subsequent steps are basically the same as in the first embodiment. Specifically, the structure shown in FIG. 35, which corresponds to FIG. 22, is obtained by carrying out the step of forming the interlayer insulating film L, the step of making through holes S4, and the step of forming plugs P4 in the same way as in the first embodiment. Since the subsequent steps are the same as in the first embodiment, figures and explanations concerning the steps are not given here.

The third embodiment has the same features as the first, second, and third features of the first embodiment.

The third embodiment also brings about almost the same advantageous effects as the first embodiment.

However, in the first embodiment, since the lower electrode LE is contained in the upper electrode UE in plan view, the entire lower electrode LE faces the upper electrode UE through the capacitive insulating film YZ. Therefore, the entire lower electrode LE can function as an effective electrode of the capacitor and it is easier to increase the capacitance value of the capacitor CP. For this reason, the first embodiment is advantageous in making a large-capacity capacitor. Also, the first embodiment is advantageous in reducing the size (area) of the semiconductor device because the area required for a capacitor with a large capacitance value can be reduced.

On the other hand, if the capacitance value of the capacitor CP need not be so large, when the lower electrode LE has a portion overlapping the upper electrode UE and a portion not overlapping it in plan view as in the third embodiment, the capacitance value of the capacitor CP can be controlled by adjusting the area of overlap between the lower electrode LE and upper electrode UE. This makes it easier to design a semiconductor device having a capacitor. For example, it is easier to change the design of a semiconductor device having a capacitor since the capacitance value of the capacitor CP can be controlled to the desired value by changing only the arrangement of the upper electrode UE and adjusting the area of overlap between the lower electrode LE and upper electrode UE.

In the third embodiment, the lower electrode LE has a portion not overlapping the upper electrode UE in plan view. In this case, it may be possible that a plug P4 is located over the lower electrode's portion not overlapping the upper electrode UE and the plug P4 is coupled to the lower electrode LE. However, if that is the case, the height of the plug P4 located over the lower electrode LE would be different from the plug P4 located over the wiring M3 because of the difference in thickness between the lower electrode LE and wiring M3. In that case, the depth of the through hole made over the lower electrode LE would be different from the depth of the through hole S4 made over the wiring M3, thereby causing over-etching of the wiring M3 or the lower electrode LE at the bottom of the through hole S4.

On the other hand, in the third embodiment, in which the lower electrode LE has a portion not overlapping the upper electrode UE in plan view, a contact plug coupled to the lower electrode LE (plug P3a in this example) is located not over the lower electrode LE but under the lower electrode LE. The third embodiment also has the same feature as the above third feature that the plug P3a buried in the interlayer insulating film L3 is located under the lower electrode LE and the plug P3a is electrically coupled to the lower electrode LE. Since the plug (P3a) coupled to the lower electrode LE is formed under the lower electrode LE, it is unnecessary to form, over the lower electrode LE, a plug (P4) to be coupled to the lower electrode LE. Therefore, in the etching step for making through holes S4 in the interlayer insulating film L4, it is unnecessary to make a through hole S4 to reach the lower electrode LE, so over-etching of the wiring M3 or the lower electrode LE at the bottom of the through hole S4 due to the step of making a through hole S4 to reach the lower electrode LE is avoided. Consequently the reliability of the capacitor CP and wiring M3 is enhanced. Thus, the reliability of the semiconductor device is enhanced.

Furthermore, in the third embodiment, the size or shape of the lower electrode LE can be changed without altering the capacitance value of the capacitor CP, namely the area of overlap between the lower electrode LE and upper electrode UE, so the position of the plug P3 coupled to the lower electrode LE can be freely determined and the freedom in the circuit design layout of the semiconductor device is increased.

Furthermore, in the third embodiment, the plug P3a coupled to the lower electrode LE may be located so as not to overlap the upper electrode UE in plan view. By doing so, the plug P3a coupled to the lower electrode LE is made remoter from the upper electrode UE can be increased so that the parasitic capacitance between the plug P3a and upper electrode UE is reduced. Therefore, the actual capacitance value of the capacitor CP can be made closer to the design value.

### Fourth Embodiment

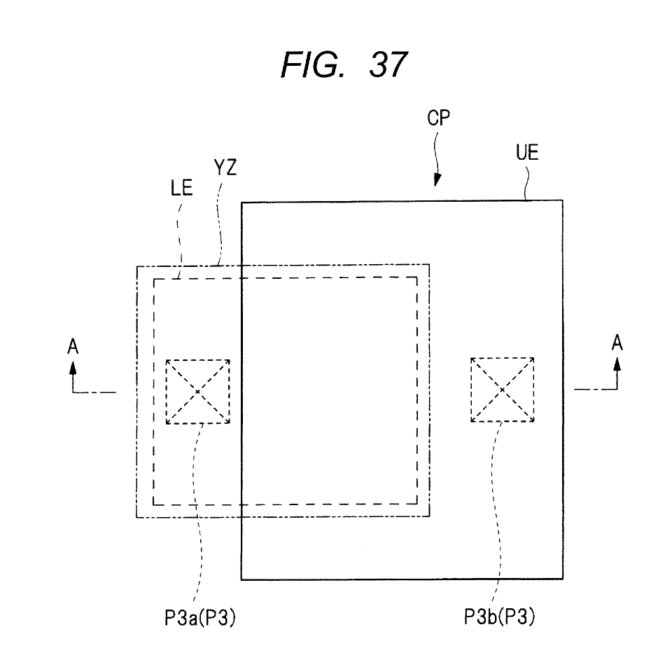

FIG. 36 is a sectional view of an essential part of the semiconductor device according to the fourth embodiment which corresponds to FIG. 1 for the first embodiment. FIG. 37 is a plan view of the essential part of the semiconductor device according to the fourth embodiment which corresponds to FIG. 2 for the first embodiment.

The fourth embodiment is a combination of the second and third embodiments. The difference between the fourth and third embodiments is the same as the difference between the second and first embodiments and the difference between the fourth and second embodiments is the same as the difference between the third and first embodiments.

Specifically, the fourth embodiment corresponds to a variation of the third embodiment in which the plug P3b is provided in place of the plug P4b as in the second embodiment. The fourth embodiment also corresponds to a variation of the second embodiment in which the lower electrode LE is not contained in the upper electrode UE in plan view but the lower electrode LE has a portion overlapping the upper electrode UE and a portion not overlapping it.

Therefore, as shown in FIGS. 36 and 37, in the fourth embodiment, the contact plug coupled to the upper electrode UE is not a plug P4 buried in a through hole S4 of the interlayer insulating film L4 but a plug P3b buried in a through hole S3 of the interlayer insulating film L3 and the plug P3b is located under the upper electrode UE's portion not overlapping the lower electrode LE in plan view. In the fourth embodiment, the lower electrode LE has a portion overlapping the upper electrode UE and a portion not overlapping it in plan view as shown in FIGS. 36 and 37. In other words, in the fourth embodiment, in plan view, while the lower electrode LE is contained in the capacitive insulating film YZ, the upper electrode UE overlaps the lower electrode LE not entirely but partially. Specifically, while the entire lower electrode LE is covered by the capacitive insulating film YZ, the upper electrode UE does not cover the capacitive insulating film YZ entirely and the lower electrode LE has a portion facing the upper electrode UE through the capacitive insulating film YZ and a portion not facing the upper electrode UE through the capacitive insulating film YZ.

Basically, the other elements of the fourth embodiment are the same as in the first embodiment.

The fourth embodiment also brings about almost the same advantageous effects as the second and third embodiments. The description of the advantageous effects is omitted here.

### Fifth Embodiment

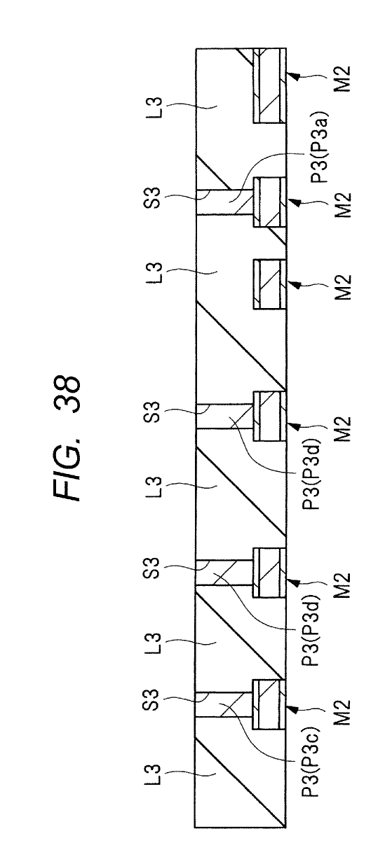

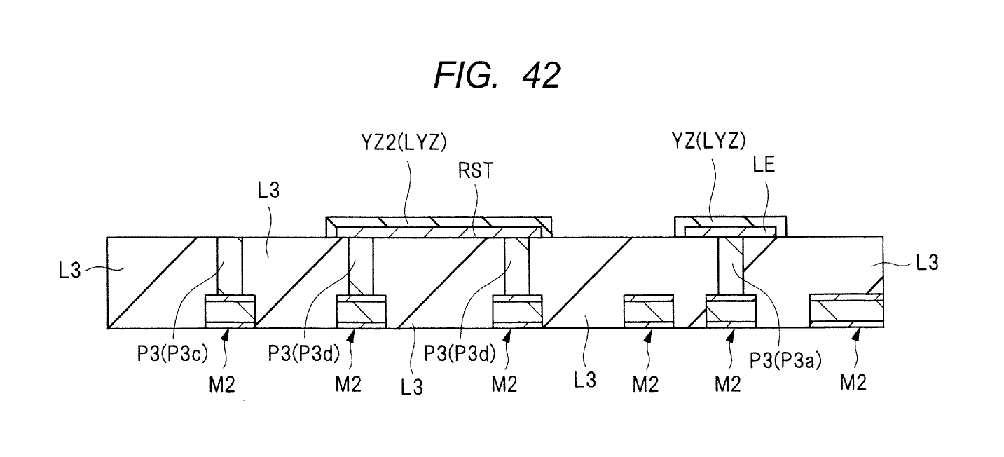

FIGS. 38 to 45 are sectional views of an essential part of the semiconductor device in manufacturing steps according to the fifth embodiment. FIGS. 38, 39, 40, and 41 correspond to the steps shown in FIGS. 12, 13, 14, and 15 in the first embodiment, respectively. FIGS. 42, 43, 44, and 45 correspond to the steps shown in FIGS. 16, 17, 19, and 24 in the first embodiment, respectively.

In the fifth embodiment, a resistor RST is formed from a conductive film pattern in the same layer as the lower electrode. Next, the fifth embodiment will be described concretely with focus on the semiconductor device manufacturing process.

The structure shown in FIG. 38 which corresponds to FIG. 12 for the first embodiment is obtained by carrying out the same steps until and including the formation of plugs P3 as in the first embodiment. In the fifth embodiment, as shown in FIG. 38, when through holes S3 are made in the interlayer insulating film L3, through holes S3 for burying plugs P3d are also made and when plugs P3 are formed in the through holes S3, plugs P3d are also formed.

Among the plugs P3, a plug P3 located under a resistor RST (which will be described later) and electrically coupled to the resistor RST is designated by sign P3d and hereinafter called plug P3d.

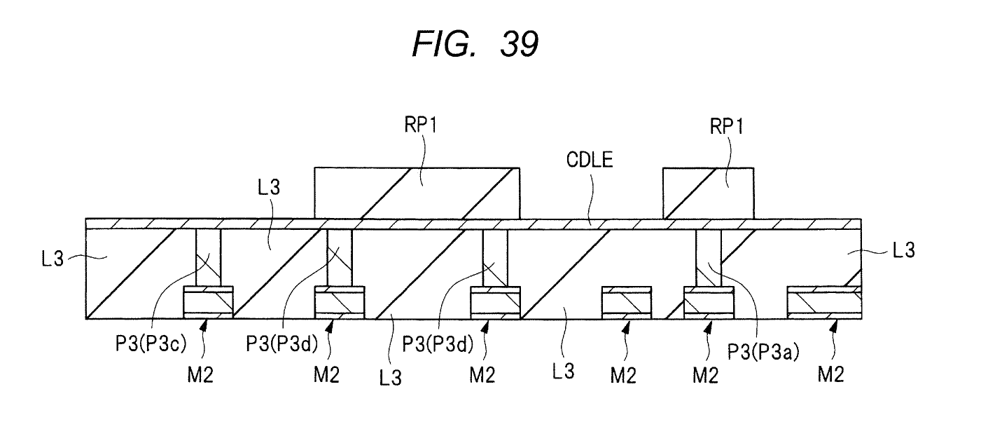

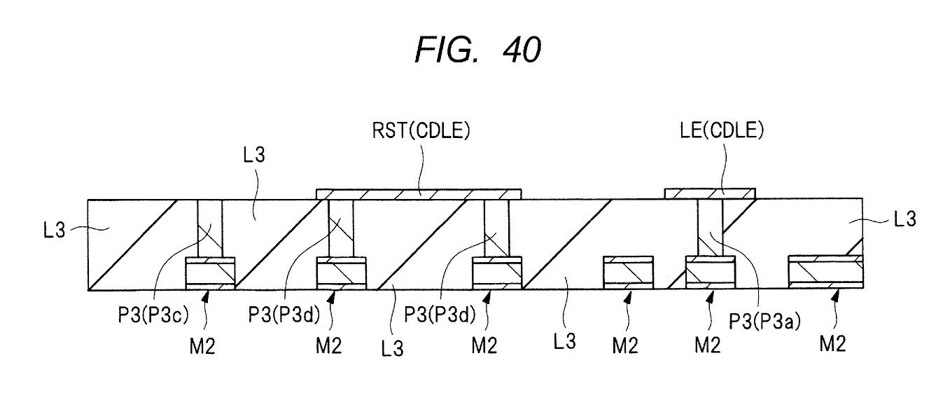

Next, as shown in FIG. 39, which corresponds to FIG. 13, a conductive film CDLE is formed over the interlayer insulating film L3 in which the plugs P3 are buried, as in the first embodiment. In the fifth embodiment, the conductive film CDLE functions as both a conductive film for the formation of the lower electrode LE and a conductive film for the formation of the resistor RST. Then, a photoresist pattern RP1 is made over the conductive film CDLE by photolithography. In the fifth embodiment, the photoresist pattern RP1 includes not only a pattern for the lower electrode LE but also a pattern for the resistor RST. Then, the lower electrode LE and the resistor RST are formed as shown in FIG. 40 by patterning (etching) the conductive film CDLE using the photoresist pattern RP1 as an etching mask. The lower electrode LE and the resistor RST are both patterned conductive films CDLE. Thus the lower electrode LE and the resistor RST are formed from the conductive film patterns in the same layer. The lower electrode LE and the resistor RST are separated from each other. The lower electrode LE and the resistor RST are formed in the same step. After that, the photoresist pattern RP1 is removed. FIG. 39 shows the result of removal of the pattern.

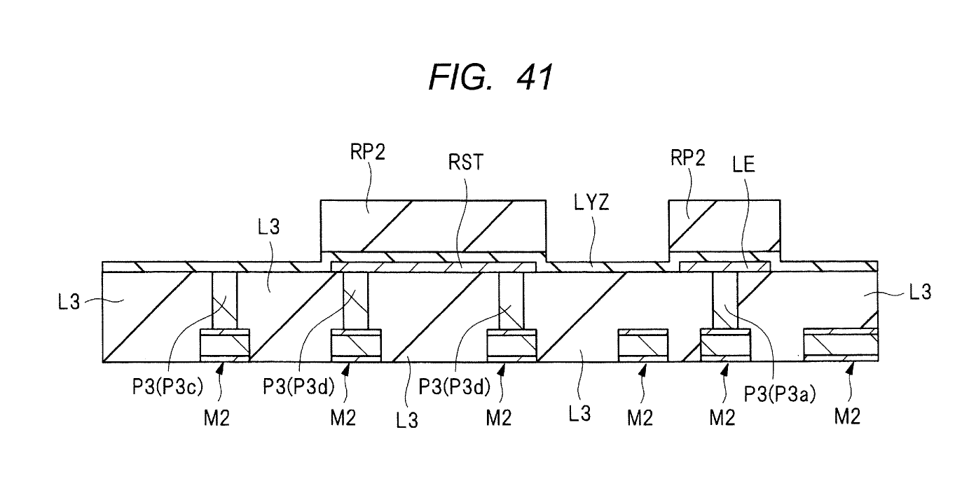

Then, as shown in FIG. 41, which corresponds to FIG. 15, an insulating film LYZ for the formation of a capacitive insulating film YZ is formed over the main surface (whole main surface) of the semiconductor substrate SB, namely the interlayer insulating film L3, so as to cover the lower electrode LE and the resistor RST. Then, a photoresist pattern RP2 is made over the insulating film LYZ by photolithography. In the fifth embodiment, the photoresist pattern RP2 includes not only a pattern for the formation of the capacitive insulating film YZ but also a pattern for the formation of a cap insulating film YZ2. Then, the capacitive insulating film YZ and the cap insulating film YZ2 are formed as shown in FIG. 42 by patterning (etching) the insulating film LYZ using the photoresist pattern RP2 as an etching mask. The capacitive insulating film YZ and the cap insulating film YZ2 are both patterned insulating films LYZ. Thus the capacitive insulating film YZ and the cap insulating film YZ2 are formed from the conductive film patterns in the same layer. The capacitive insulating film YZ and the cap insulating film YZ2 are separated from each other. After that, the photoresist pattern RP2 is removed. FIG. 42 shows the result of removal of the pattern.

In plan view, the lower electrode LE is contained in the capacitive insulating film YZ, which means that when the capacitive insulating film LE is formed, the lower electrode LE is covered by the capacitive insulating film YZ and thus the lower electrode LE is not exposed. Also, in plan view, the resistor RST is contained in the capacitive insulating film YZ2, which means that when the cap insulating film YZ2 is formed, the resistor RST is covered by the cap insulating film YZ2 and thus the resistor RST is not exposed.

In the fifth embodiment, the subsequent steps are basically the same as in the first embodiment.

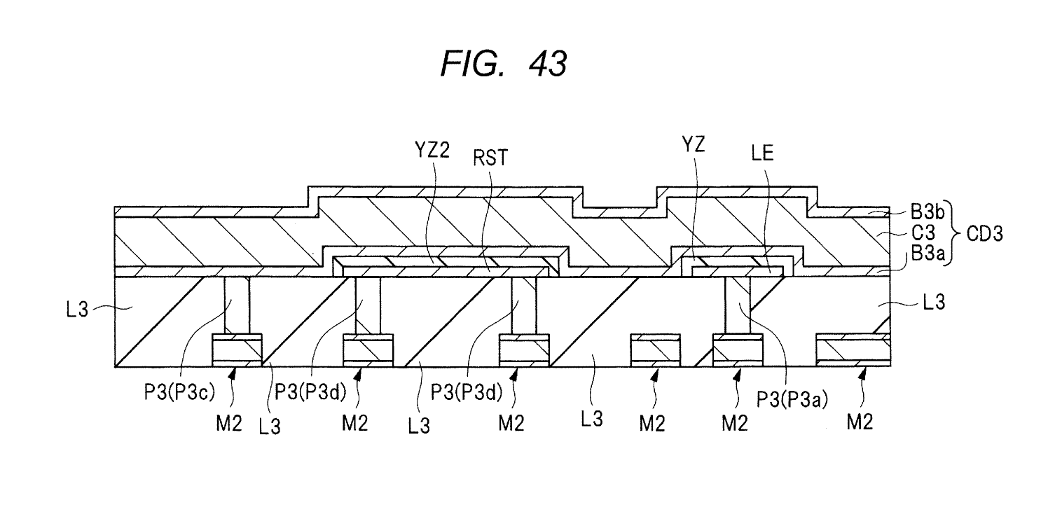

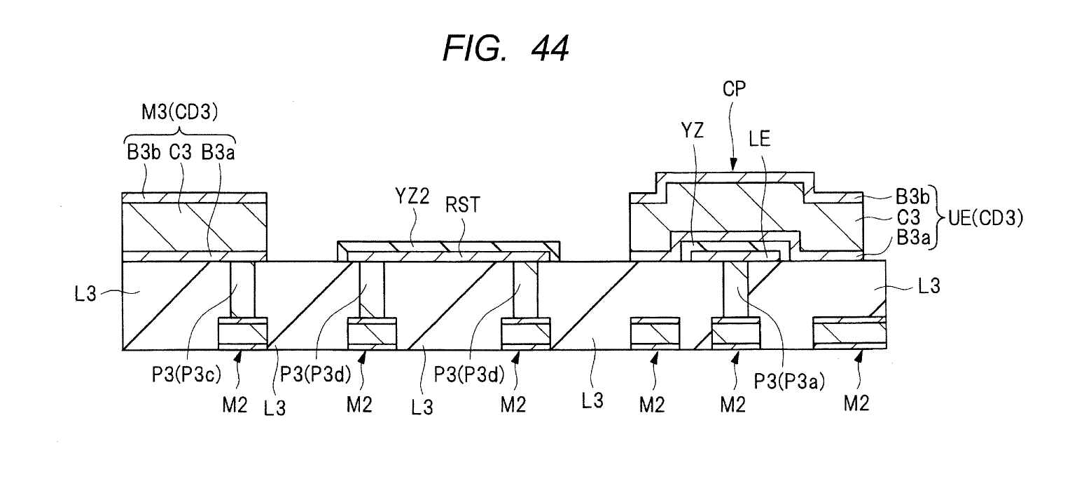

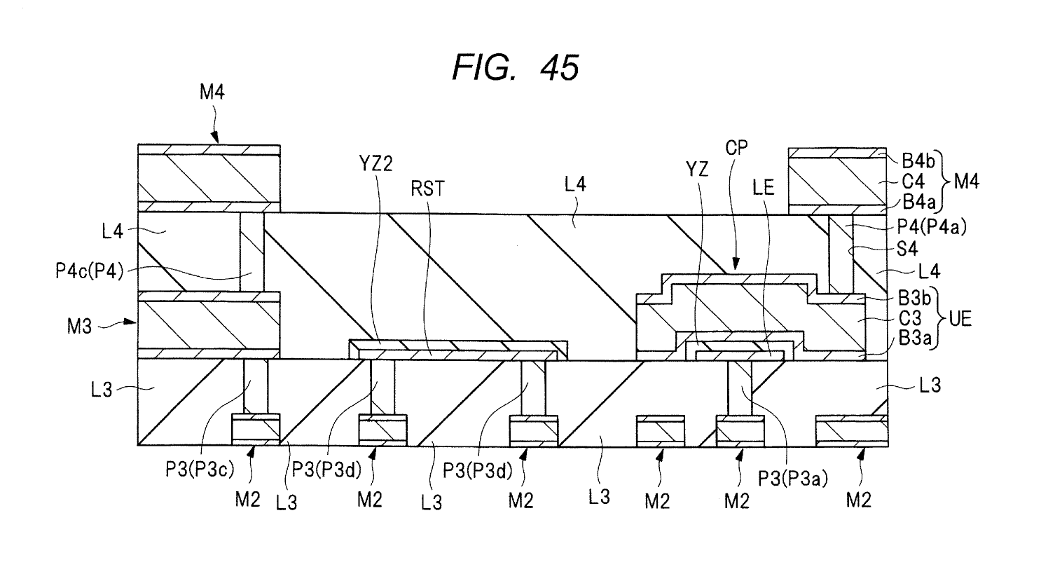

Specifically, as shown in FIG. 43, which corresponds to FIG. 17, a conductive film CD3 is formed over the main surface (whole main surface) of the semiconductor substrate SB, namely the interlayer insulating film L3, so as to cover the capacitive insulating film YZ and the cap insulating film YZ2. The conductive film CD3 is a laminated film which includes a barrier conductive film B3a, a main conductive film C3 over the barrier conductive film B3a, and a barrier conductive film B3b over the main conductive film C3. Then, the wiring M3 and the upper electrode UE are formed as shown in FIG. 44, which corresponds to FIG. 19, by patterning the conductive film CD3 as in the first embodiment. The wiring M3 and the upper electrode UE are both patterned conductive films CD3. In the etching step for patterning the conductive film CD3, the cap insulating film YZ2 is exposed but the resistor RST is covered by the cap insulating film YZ2 to prevent etching of the resistor RST. Thus, the cap insulating film YZ2 functions as a protective film to prevent etching of the resistor RST.

Then, as shown in FIG. 45, which corresponds to FIG. 24, as in the first embodiment, an interlayer insulating film L4 is formed, through holes S4 are made in the interlayer insulating film L4, plugs P4 are formed in the through holes S4, and wirings M4 in the fourth wiring layer are formed over the interlayer insulating film L4 in which the plugs P4 are buried. The figures of the subsequent steps and their descriptions are omitted here.

As can be known from FIG. 45, in the semiconductor device according to the fifth embodiment, the capacitor CP and the resistor RST are formed over the interlayer insulating film L3 and the lower electrode LE of the capacitor CP and the resistor RST are from the conductive patterns in the same layer. In other words, the lower electrode LE and the resistor RST are formed by patterning the same conductive film (CD3). The lower electrode LE and the resistor RST are not coupled and separated from each other. The material of the lower electrode LE is the same as the material of the resistor RST. Also the thickness of the lower electrode LE is virtually equal to the thickness of the resistor RST.

The fifth embodiment is the same as any one of the first to fourth embodiments except that it includes the resistor RST, the cap insulating film YZ2, and the plugs P3d coupled to the resistor RST. In other words, the fifth embodiment may be applied to any one of the first to fourth embodiments. Although the figures and descriptions given here are mostly based on the assumption that it is applied to the first embodiment, the resistor RST may also be formed in the second to fourth embodiments, in which the structures of the resistor RST, cap insulating film YZ2, and contact plugs (plugs P3d) coupled to the resistor RST and the steps of forming them are the same as in the fifth embodiment.

The fifth embodiment brings about the following advantageous effects in addition to those brought about by any one of the first to fourth embodiments.

In the fifth embodiment, since the resistor RST and lower electrode LE are formed from the conductive film patterns in the same layer, the resistor RST can be formed during the steps of forming the capacitor CP. Thus, the number of manufacturing steps can be decreased and the semiconductor device manufacturing cost can be reduced. In addition, the time required to manufacture the semiconductor device can be shortened, leading to improvement in throughput.

Furthermore, in the fifth embodiment, the plugs P3d (contact plugs) buried in the interlayer insulating film L4 are located under the resistor RST and electrically coupled to the resistor RST. A plug P4 (contact plug) which is buried in the interlayer insulating film L4 and coupled to the resistor RST is not formed over the resistor RST.

In other words, a contact plug coupled to the resistor RST is not a plug P4 buried in a through hole S4 of the interlayer insulating film L4 but a plug P3 (P3d) buried in a through hole S3 of the interlayer insulating film L3.

A plug P3d is located under the resistor RST and a wiring M2 is located under the plug P3d. The plug P3d is located between the resistor RST and wiring M2 and the upper surface of the plug P3d abuts on the lower surface of the resistor RST so that the plug P3d and resistor RST are electrically coupled, and the lower surface of the plug P3d abuts on the upper surface of the wiring M2 so that the plug P3d and wiring M2 are electrically coupled. Thus, the plug P3d functions to couple the resistor RST and the wiring M2 underlying the plug P3d electrically.

It is assumed that a case different from the fifth embodiment, in which a plug P4 is located over the resistor RST and the plug P4 is coupled to the resistor RST. In this case, because of the difference in thickness between the lower electrode LE and the wiring M3, the height of the plug P4 located over the resistor RST would be different from the height of the plug P4 located over the wiring M3. Also, in this case, because the depth of the through hole S4 made over the resistor RST is different from the depth of the through hole S4 made over the wiring M3, the wiring M3 or the resistor RST would be over-etched at the bottom of the through hole S4.

In contrast, in the fifth embodiment, the contact plugs (plugs P3d) coupled to the resistor RST are formed not over the resistor RST but under the resistor RST. Therefore, a plug (P4) to be coupled to the lower electrode LE need not be formed over the resistor RST. Therefore, in the etching step for making through holes S4 in the interlayer insulating film L4, it is unnecessary to make a through hole S4 to reach the resistor RST, which avoids over-etching of the wiring M3 or the resistor RST at the bottom of the through hole S4 which might be caused by making a through hole S4 to reach the resistor RST. Consequently the reliability of the resistor RST and wiring M3 is enhanced. Thus, the reliability of the semiconductor device is enhanced.

The invention made by the present inventors has been so far explained concretely in reference to the preferred embodiments thereof. However, the invention is not limited thereto and it is obvious that these details may be modified in various ways without departing from the gist thereof.

What is claimed is:

1. A semiconductor device comprising:
a semiconductor substrate;
a first interlayer insulating film formed over the semiconductor substrate;
a first wiring and a lower electrode for a capacitor being formed over the first interlayer insulating film and spaced from each other;
an upper electrode for the capacitor being formed over the first interlayer insulating film so as to cover the lower electrode at least partially;
a capacitive insulating film for the capacitor, interposed between the lower electrode and the upper electrode;
a second interlayer insulating film formed over the first interlayer insulating film so as to cover the first wiring, the lower electrode, the capacitive insulating film, and the upper electrode;
a first contact plug buried in the first interlayer insulating film, the first contact plug being located under the lower electrode and electrically coupled to the lower electrode;
a second contact plug buried in the second interlayer insulating film, the second contact plug being located over the upper electrode and electrically coupled to the upper electrode; and
a third contact plug buried in the second interlayer insulating film, the third contact plug being located over the first wiring and electrically coupled to the first wiring,
wherein the first wiring and the upper electrode are formed from a conductive film pattern in a layer, and
wherein the second contact plug is located over a portion of the upper electrode not overlapping the lower electrode in plan view.

2. The semiconductor device according to claim 1,
wherein a contact plug to be buried in the second interlayer insulating film and coupled to the upper electrode is not formed over a portion of the upper electrode overlapping the lower electrode in plan view.

3. The semiconductor device according to claim 2,
wherein the first wiring is an aluminum wiring which contains aluminum as a main component, and
wherein the lower electrode is made of a material having a higher melting point than a melting point of aluminum.

4. The semiconductor device according to claim 3,
wherein the lower electrode is a titanium nitride film, titanium film, tantalum nitride film or tantalum film.

5. The semiconductor device according to claim 1,
wherein the first wiring and the upper electrode are each a laminated film including a first titanium nitride film, an aluminum-based main conductive film over the first titanium nitride film, and a second titanium nitride film over the main conductive film, and
wherein the lower electrode is a titanium nitride film.

6. The semiconductor device according to claim 1,
wherein in plan view, the lower electrode is contained in the capacitive insulating film and the capacitive insulating film is contained in the upper electrode.

7. The semiconductor device according to claim 1,
wherein in plan view, the lower electrode has a portion overlapping the upper electrode and a portion not overlapping the upper electrode, and
wherein in plan view, a contact plug to be buried in the second interlayer insulating film and coupled to the lower electrode is not formed over the portion of the lower electrode not overlapping the upper electrode.

8. The semiconductor device according to claim 1, further comprising a resistor formed over the second interlayer insulating film,
wherein the resistor and the lower electrode are formed from a conductive film pattern in a layer,
wherein a fourth contact plug buried in the first interlayer insulating film is located under the resistor and electrically coupled to the resistor, and
wherein a contact plug to be buried in the second interlayer insulating film and coupled to the resistor is not formed over the resistor.

9. The semiconductor device according to claim 1, wherein a thickness of the lower electrode is smaller than a thickness of the first wiring.

10. A semiconductor device comprising:
a semiconductor substrate;
a first interlayer insulating film formed over the semiconductor substrate;
a first wiring and a lower electrode for a capacitor being formed over the first interlayer insulating film and spaced from each other;
an upper electrode for the capacitor being formed over the first interlayer insulating film so as to cover the lower electrode at least partially;
a capacitive insulating film for the capacitor, interposed between the lower electrode and the upper electrode;
a second interlayer insulating film formed over the first interlayer insulating film so as to cover the first wiring, the lower electrode, the capacitive insulating film, and the upper electrode;
a first contact plug buried in the first interlayer insulating film, the first contact plug being located under the lower electrode and electrically coupled to the lower electrode;
a second contact plug buried in the first interlayer insulating film, the second contact plug being located under the upper electrode and electrically coupled to the upper electrode; and
a third contact plug buried in the second interlayer insulating film, the third contact plug being located over the first wiring and electrically coupled to the first wiring,
wherein the first wiring and the upper electrode are formed from a conductive film pattern in a layer, and
wherein the second contact plug is located under a portion of the upper electrode not overlapping the lower electrode in plan view.

11. The semiconductor device according to claim 10,
wherein a contact plug to be buried in the second interlayer insulating film and coupled to the upper electrode is not formed over a portion of the upper electrode overlapping the lower electrode in plan view.

12. The semiconductor device according to claim 11,
wherein the first wiring is an aluminum wiring which contains aluminum as a main component, and
wherein the lower electrode is made of a material having a higher melting point than a melting point of aluminum.

13. The semiconductor device according to claim 12,
wherein the lower electrode is a titanium nitride film, titanium film, tantalum nitride film or tantalum film.

14. The semiconductor device according to claim 10,
wherein the first wiring and the upper electrode are each a laminated film including a first titanium nitride film, an aluminum-based main conductive film over the first titanium nitride film, and a second titanium nitride film over the main conductive film, and
wherein the lower electrode is a titanium nitride film.

15. The semiconductor device according to claim 10, wherein in plan view, the lower electrode is contained in the capacitive insulating film and the capacitive insulating film is contained in the upper electrode.

16. The semiconductor device according to claim 10,
wherein in plan view, the lower electrode has a portion overlapping the upper electrode and a portion not overlapping the upper electrode, and
wherein in plan view, a contact plug to be buried in the second interlayer insulating film and coupled to the lower electrode is not formed over the portion of the lower electrode not overlapping the upper electrode.

17. The semiconductor device according to claim 10, further comprising a resistor formed over the second interlayer insulating film,
wherein the resistor and the lower electrode are formed from a conductive film pattern in a layer,
wherein a fourth contact plug buried in the first interlayer insulating film is located under the resistor and electrically coupled to the resistor, and
wherein a contact plug to be buried in the second interlayer insulating film and coupled to the resistor is not formed over the resistor.

18. The semiconductor device according to claim 10,
wherein a thickness of the lower electrode is smaller than a thickness of the first wiring.
